(19) United States
(12) Patent Application Publication
(10) Pub. No.: US 2021/0376310 A1
(43) Pub. Date: Dec. 2, 2021

(54) ATOMIC LAYER DEPOSITION OF IONICALLY CONDUCTIVE COATINGS FOR LITHIUM BATTERY FAST CHARGING

(71) Applicant: THE REGENTS OF THE UNIVERSITY OF MICHIGAN, Ann Arbor, MI (US)

(72) Inventors: NEIL P. DASGUPTA, ANN ARBOR, MI (US); KUAN-HUNG CHEN, ANN ARBOR, MI (US); ERIC KAZYAK, ANN ARBOR, MI (US)

(21) Appl. No.: 17/333,485

(22) Filed: May 28, 2021

Related U.S. Application Data
(60) Provisional application No. 63/032,205, filed on May 29, 2020.

(51) Int. Cl. H01M 4/1391; H01M 4/04; H01M 4/131

(52) U.S. Cl. CPC H01M 4/1391; C23C 16/45553; H01M 4/131; H01M 4/0404

(57) ABSTRACT

A method of making an ionically conductive layer for an electrochemical device is disclosed. A film is coated on electrode material particles or post-calendered electrodes. This coating may be a lithium borate-carbonate film deposited by atomic layer deposition. One example method includes the steps of: (a) exposing a substrate including an electrode material to a lithium-containing precursor followed by an oxygen-containing precursor; and (b) exposing the substrate to a boron-containing precursor followed by the oxygen-containing precursor.

### CROSS-REFERENCES TO RELATED APPLICATIONS

This application claims priority to U.S. Patent Application No. 63/032,205 filed May 29, 2020.

### STATEMENT REGARDING FEDERALLY SPONSORED RESEARCH

This invention was made with government support under grant number DE-EE0008362 awarded by the U.S. Department of Energy. The government has certain rights in this invention.

### FIELD OF THE INVENTION

This invention relates to electrochemical devices, such as lithium battery electrodes, thin film lithium batteries, and lithium batteries including these electrodes.

### BACKGROUND

The ability to quickly recharge lithium-ion batteries (LIBs) is of critical importance to the widespread commercialization of electric vehicles (EVs). One of the primary factors limiting the fast charge ability of state-of-the-art LIBs is the tendency for plating out of metallic Li on the graphite electrode during charging. This phenomenon leads to rapid capacity fading of the cell, consumption of the electrolyte (cell drying), and the potential for short-circuit from dendrites penetrating the separator.

A promising approach to fabricate conformal thin-films as either stand-alone electrolytes in thin film batteries or as interfacial layers in bulk batteries is Atomic Layer Deposition (ALD). ALD is a vapor-phase deposition process that relies on a sequence of self-limiting surface reactions to grow conformal thin films in a non-line-of-sight, layer-by-layer process. This process enables digital tunability in composition and thickness on complex geometries where traditional thin film deposition techniques fall short. In addition, many ALD processes can be carried out at relatively low temperatures (often 25° C.-250° C.), which facilitates coating of a wide range of substrate materials that would not withstand harsher conditions. Recent advances in Spatial Atomic Layer Deposition (SALD) have demonstrated dramatically faster and lower cost ALD that is compatible with high-throughput manufacturing, including roll-to-roll processing. For these reasons, many reports have investigated the use of ALD to fabricate materials for energy applications, including for various battery applications.

Following the pioneering work on ALD interlayers in Li-ion batteries, in the past 5 years, several studies have investigated ALD films as solid electrolytes. Specifically, ALD electrolytes are promising for electrochemical storage systems for three dimensional (3D) battery architectures, porous electrode coatings, encapsulation, etc. These studies have fabricated a range of oxide, phosphate, and sulfide materials with a wide range of ionic conductivities (10⁻¹⁰ to 6×10⁻⁷ S/cm). The highest reported ionic conductivity in ALD films is in LiPON films (3.7×10⁻⁷ S/cm in solid-state or 6.6×10⁻⁷ S/cm in liquid cell). These materials have been used to make thin-film batteries, and have shown promising electrochemical stability for application in high voltage systems. One potential limitation of the ALD LiPON films is that the ionic conductivity still lags behind that of sputtered LiPON (2×10⁻⁶ S/cm) and well behind that of bulk solid state electrolytes (10⁻⁴ to 10⁻² S/cm). For this reason, materials with higher ionic conductivities that still maintain wide electrochemical stability windows are of great interest to the community.

Previous work has demonstrated an ALD process for the pentenary oxide material Al-doped Li₇La₃Zr₂O₁₂, one of the most promising bulk solid electrolytes. Unfortunately, the ionic conductivity of the amorphous as-deposited films was relatively low (˜10⁻⁸ S/cm), and the morphology evolution during annealing made application in batteries challenging. As such, ALD films that exhibit high ionic conductivity without requiring high temperature annealing are preferable. In this regard, amorphous/glassy electrolytes are particularly attractive due to the detrimental effects of grain boundary resistance and intergranular Li metal propagation in many crystalline materials.

What is needed therefore are methods of making improved lithium-ion batteries having reduced tendency for plating out of metallic lithium on the graphite electrode during charging.

### SUMMARY OF THE INVENTION

The present disclosure provides methods of making improved lithium-ion batteries having reduced tendency for plating out of metallic lithium on the graphite electrode during charging. A surface coating is implemented on graphite particles or the post-calendered electrodes. This coating may be a lithium borate-carbonate (LBCO) film deposited by atomic layer deposition (ALD). The film may conformally coat the graphite particles, due to the fact that ALD relies on self-limiting reactions and is not line-of-sight.

The film has previously been shown to exhibit ionic conductivities above 2×10⁻⁶ S/cm and excellent electrochemical stability. The system and method for depositing this film on a solid-state-batteries as an interfacial layer or stand-alone solid-electrolyte are discussed in further details in U.S. Patent Application Publication No. 2020/0028208, which is incorporated by reference as if set forth in its entirety herein for all purposes. The present disclosure demonstrates dramatic improvements to liquid-electrolyte-based lithium-ion battery performance by applying the LBCO ALD film to graphite electrodes, enabling fast-charging of high loading (>3 mAh/cm²) electrodes in 15 minutes with minimal capacity fading. The films used are also thinner than those proposed in U.S. Patent Application Publication No. 2020/0028208.

The present disclosure provides methods for forming an electrochemical device using an ALD. In one aspect, a Li₃BO₃—Li₂CO₃ (LBCO) film is produced using ALD. The ALD LBCO film growth is self-limiting and linear over a range of deposition temperatures. The ability to tune the structure and properties of the film with deposition conditions and post-treatments is demonstrated for this film. Higher ionic conductivity than any previously reported ALD film (>10⁻⁶ S/cm at room temperature) with an ionic transference number of >0.9999 is achieved, and the film was shown to be stable over a wide range of potentials relevant for liquid-electrolyte-based batteries.

In one aspect, the present disclosure provides a method of making a film for an electrochemical device. The method includes the steps of: (a) exposing a substrate to a lithium-containing precursor followed by an oxygen-containing precursor; and (b) exposing the substrate to a boron-containing precursor followed by the oxygen-containing precursor whereby a film is formed.

In the method, the electrochemical device can be a cathode or an anode.

In the method, the film can be comprised of boron, carbon, oxygen, and lithium.

In the method, step (a) can be continuously repeated between 1 and 10 times during a first subcycle and/or step (b) can be continuously repeated between 1 and 10 times during a second subcycle. In the method, both the first subcycle and second subcycle can be repeated between 1 and 5000 times in a supercycle.

In the method, the lithium-containing precursor may comprise a lithium alkoxide. In another embodiment of the method, the lithium-containing precursor may comprise lithium tert-butoxide. The lithium-containing precursor can be selected from the group consisting of lithium tert-butoxide, tetramethylheptanedionate, lithium hexamethyldisilazide, and mixtures thereof.

In the method, the boron-containing precursor may comprise a boron alkoxide. In the method, the boron-containing precursor may comprise triisopropylborate. The boron-containing precursor may be selected from the group consisting of triisopropylborate, boron tribromide, boron trichloride, triethylboron, tris(ethyl-methylamino) borane, trichloroborazine, tris(dimethylamido)borane, trimethylborate, diboron tetrafluoride, and mixtures thereof.

In the method, the oxygen-containing precursor can be selected from the group consisting of ozone, water, oxygen plasma, ammonium hydroxide, oxygen, and mixtures thereof. In one version of the method, the oxygen-containing precursor comprises ozone.

In the method, the lithium-containing precursor, the boron-containing precursor, and the oxygen-containing precursor can be in a gaseous state.

In the method, the film can have a thickness of 0.1 to 50 nanometers.

In the method, the film can have an ionic conductivity of greater than 1.0×10⁻⁷ S/cm. Additionally, in the method, the film can have an ionic transference number of greater than 0.9999 from 0-6 volts vs lithium metal.

In the method, step (a) and step (b) can occur at a temperature between 50° C. and 280° C. In another embodiment of the method, step (a) and step (b) can occur at a temperature between 200° C. and 220° C. Additionally, in the method, step (a) and step (b) occur in the presence of ozone. In one embodiment, step (a) can occur before step (b), and in another embodiment, step (b) can occur before step (a).

In the method, the film can be annealed in a temperature range of 100° C. to 500° C. after step (a) and step (b).

This disclosure also provides a film formed by any embodiments of the method described above.

In another aspect, the present disclosure provides a method of making an electrochemical device. The method includes the steps of: (a) exposing a substrate to a lithium-containing precursor followed by an oxygen-containing precursor; and (b) exposing the substrate to a boron-containing precursor followed by the oxygen-containing precursor, wherein an film can be formed on the substrate, and wherein the substrate can be selected from an anode or a cathode.

In another embodiment of the method, the substrate can be an anode. In the method, the anode may comprise of a material selected from the group consisting of lithium metal, magnesium metal, sodium metal, zinc metal, graphite, lithium titanate, hard carbon, tin/cobalt alloy, silicon, silicon-carbon composites, transition-metal oxides, transition-metal sulfides, and transition-metal phosphides, soft carbon, and mixtures thereof. In this embodiment, the anode material can comprise graphite.

In the method, the substrate can be a cathode. The cathode can comprise a material selected from the group consisting of (i) lithium metal oxides wherein the metal is one or more aluminum, cobalt, iron, manganese, nickel and vanadium, (ii) lithium-containing phosphates having a general formula LiMPO₄ wherein M is one or more of cobalt, iron, manganese, and nickel, (iii) V₂O₅, (iv) porous carbon, (v) sulfur containing materials, and (vi) a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811).

In the method, the substrate can be planar, and/or three dimensional, and/or corrugated. Additionally, in the method, the substrate can be a high-aspect-ratio three dimensional structure.

In the method, the film can be a film that is comprised of boron, carbon, oxygen, and lithium.

In the method, step (a) can be continuously repeated between 1 and 10 times in a first subcycle. Additionally, in the method, step (b) can be continuously repeated between 1 and 10 times in a second subcycle. The first subcycle and second subcycle can be repeated between 1 and 5000 times in a supercycle.

In the method, the lithium-containing precursor may comprise a lithium alkoxide. In the method, the lithium-containing precursor can be selected from the group consisting of lithium tert-butoxide, tetramethylheptanedionate, lithium hexamethyldisilazide, and mixtures thereof. Additionally, in the method, the boron-containing precursor can comprise triisopropylborate.

In the method, the oxygen-containing precursor can be selected from the group consisting of ozone, water, oxygen plasma, ammonium hydroxide, oxygen, and mixtures thereof. In another embodiment of the method, the oxygen-containing precursor can comprise ozone.

In the method, the lithium-containing precursor, the boron-containing precursor, and the oxygen-containing precursor can be in a gaseous state. In the method, the film can have a thickness of 0.1 to 50 nanometers.

In the method, the film can have an ionic conductivity of greater than 1.0×10⁻⁷ S/cm. Additionally, in the method, the film can have an ionic transference number of greater than 0.9999 from 0-6 volts vs lithium metal.

In the method, step (a) and step (b) can occur at a temperature between 50° C. and 280° C. In another embodiment of the method, step (a) and step (b) can occur at a temperature between 200° C. and 220° C.

In the method, step (a) and step (b) can occur in the presence of ozone. Additionally, in the method, step (a) can occur before step (b). In another embodiment of the method, step (b) can occur before step (a).

In the method, the film can be amorphous.

The present disclosure covers the deposition of nanoscale lithium borate-based or lithium carbonate-based thin films onto electrode materials/particles (positive and/or negative electrode) to enable faster charging rates by reducing polarization, improving transport, and/or reducing/preventing lithium plating. Negative electrode materials could include carbonaceous materials (graphite, soft carbon, hard carbon) and composites thereof, composites of graphite and Si, lithium titanate (LTO), lithium metal, etc. Positive electrode materials could include NMC (111, 532, 622, 811, etc.), NCA, NMCA, LFP, LMO, LMNO, and composites thereof, etc.

The film could be deposited on electrodes after calendering (including binder and additives) or on powders before casting. The present disclosure provides materials with high ionic conductivity (>1.0×10⁻⁷ S/cm at room temperature) and good electrochemical stability at low potentials vs. Li/Li+. Without intending to be bound by theory, at least three mechanisms may be involved with use of the film. i.e., the film could alter the wettability of the liquid electrolyte, the lithium metal, or alter the solid electrolyte interphase (SEI) composition and properties. The present disclosure enables both faster charging rates and/or increased electrode loading when using the film on an anode and/or a cathode.

The foregoing and other aspects and advantages of the invention will appear from the following description. In the description, reference is made to the accompanying drawings which form a part hereof, and in which there is shown by way of illustration example embodiments of the invention. Such embodiments do not necessarily represent the full scope of the invention, however, and reference is made therefore to the claims and herein for interpreting the scope of the invention.

### BRIEF DESCRIPTION OF DRAWINGS

The patent or application file contains at least one drawing executed in color. Copies of this patent or patent application publication with color drawing(s) will be provided by the Office upon request and payment of the necessary fee.

FIG. 1 is a schematic of a thin film lithium battery.

FIG. 2 depicts a process flowchart of a method of making a lithium borate-carbonate film.

FIG. 3 depicts cycling performance of graphite/NMC 532 coin cells with and without LBCO ALD coatings on the graphite electrodes, wherein (A) shows discharge capacity vs. cycle number, and wherein (B) shows Coulombic efficiency vs. cycle number, and wherein (C) shows Energy efficiency vs. cycle number.

FIG. 4 depicts the voltage profiles for cycle 10 of 4C fast-charge cycling, wherein (A) shows the charge voltage profile, and wherein (B) shows the discharge voltage profile along with dQ)/dV.

FIG. 5 depicts a demonstration of LBCO ALD coating approach for graphite electrodes. (A) is a schematic of the electrode fabrication process including slurry-casting, calendaring, ALD, and cell assembly. (B,C) are SEM images of a torn cross-section of LBCO 500x coated graphite electrode, (D) is an SEM image of focused-ion beam cross-section through a single graphite particle showing the conformal LBCO encapsulation of the particle. (E) is an XPS survey scan and calculated composition of 250x LBCO-coated electrode surface.

FIG. 6 depicts SEI formation during a first preconditioning cycle. (A) is a charge curve for first preconditioning cycle of graphite-NMC532 coin cells with varying thicknesses of the LBCO coating on the graphite electrode. (B) is differential voltage curves corresponding to the SEI formation plateau in (A). (C) is a schematic of the surface film evolution during preconditioning for control and LBCO 250x electrodes. (D) is the composition of electrode surface at various stages of preconditioning as measured by XPS after 60 seconds of Ar sputtering to reduce adventitious species.

FIG. 7 depicts extended cycling of NMC532/graphite pouch cells with and without LBCO coating. (A) is a discharge capacity for each cell over the first 100 fast-charge cycles and 3 capacity checks. (B) is a discharge capacity for only periodic C/3 capacity-check cycles over 500 total fast-charge cycles. The 80% line is based on initial C/3 capacity check. (C) is Coulombic efficiency values for fast-charge cycles in (A). Data points for the capacity checks and the subsequent fast-charge cycles were omitted due to changes in charge/discharge rates which cause unmeaningful CE values. (D) is the discharge capacity for 4C fast-charge cycles only. The 80% line is based on initial fast-charge cycle. (E) is a charge curve for first 4C charge, and (F) is the same for 100^{th} 4C charge. For all 4C cycles, a constant current (CC) was applied until a cutoff voltage of 4.2 V, followed by a constant voltage (CV) hold until the total time for the charging step reached 15 minutes.

FIG. 8 depicts post mortem SEM images of graphite electrode cross-sections after 100 fast-charge cycles for (A) uncoated control and (B) LBCO 250x.

FIG. 9 depicts electrochemical impedance spectroscopy of graphite electrodes at various SOCs with/without LBCO ALD coating. (A) is an equivalent circuit model that was used to fit the EIS spectra. (B) is a stacked bar plot showing fitted resistance values for each resistance element of coated/uncoated electrodes at 3 different states of charge. Fitted resistances were multiplied by the area, 2.545 cm² to get area-specific resistances. (C) is a schematic illustration of the origins of each circuit component in (A). Nyquist plots of uncoated control (D) and LBCO 250x (E) electrodes with selected frequencies labelled and marked by red dots and features labelled with their corresponding source based on the equivalent circuit model.

FIG. 10 depicts fast-charging and Li plating in 3-electrode cells. (A) is graphite electrode potential vs. Li/Li+ during and after 4C fast charging of control and LBCO 250x electrodes. (B) is an optical image of uncoated control graphite electrode cross-section after charging to 50% SOC at 4C in half cell. (C) is the same for LBCO 250x electrode.

FIG. 11 depicts in (A), measured thickness of graphite electrodes after subtracting current collector thickness for control, heated control, and LBCO 250x. In (B), mass of punched electrode pieces for the same 3 treatments. Each mass/thickness measurement was taken on 5 separate areas and averaged. The error bars represent one standard deviation.

FIG. 12 depicts F 1s core scans for control and LBCO 250x electrodes after dipping into electrolyte for 30 minutes and after charging to 4.2 V.

FIG. 13 depicts B 1s core scans for LBCO 250x electrodes before (pristine) and after (Dip) dipping in LiPF₆-based electrolyte. Both are after 120 s of Ar sputtering, removing surface species. No BE shifts are evident between the two spectra, and the binding energy value for the B 1s of LBCO is consistent with our previous work (191.6 eV). This indicates that the LBCO film remains intact on the graphite surface after dipping.

FIG. 14 depicts Practical Effective Attenuation Length calculation for B 1s photoelectrons excited by Al Kα x-rays travelling through lithium fluoride. At the selected depth of 1.0 nm, the signal from the underlying film is attenuated to 74.6%, similar to the observed decrease in B 1s signal after immersion of the LBCO-coated graphite in the electrolyte.

FIG. 15 depicts in (A), discharge capacity vs. cycle life for various electrode treatments. In (B), discharge capacity is shown for various LBCO coating thicknesses at increasing charging rates. Cells were discharged at C/2 for all cycles,

FIG. 16 depicts charge and discharge curves for uncoated control and LBCO 250x pouch cells at C/10 showing similar behavior of both cells at low rates.

FIG. 17 depicts in (A), graphite electrode potential vs. Li/Li⁺ during and after 4C fast charging of control and LBCO 250x electrodes; and in (B), Nyquist plots of control electrode at four points during the OCV step, as labelled in (A); and in (C), the same for LBCO 250x electrode. The low-frequency region of the control changes significantly, whereas the LBCO-coated electrode impedance is stable throughout.

The invention will be better understood and features, aspects and advantages other than those set forth above will become apparent when consideration is given to the following detailed description thereof. Such detailed description makes reference to the drawings.

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention, Various modifications to the illustrated embodiments will be readily apparent to those skilled in the art, and the generic principles herein can be applied to other embodiments and applications without departing from embodiments of the invention, Thus, embodiments of the invention are not intended to be limited to embodiments shown, but are to be accorded the widest scope consistent with the principles and features disclosed herein, Skilled artisans will recognize the examples provided herein have many useful alternatives and fall within the scope of embodiments of the invention.

Although the systems and methods introduced herein are often described for use in an electrochemical cell or battery, one of skill in the art will appreciate that these teachings can be used for various applications (e.g. sensors, fuel cells).

The term “metal” as used herein can refer to alkali metals, alkaline earth metals, lanthanoids, actinoids, transition metals, post-transition metals, metalloids, and selenium.

One embodiment of the invention provides a method for forming a cathode wherein the method comprises: (a) exposing cathode material particles to a lithium-containing precursor followed by an oxygen-containing precursor to form a coating on the cathode material particles; (b) forming a slurry comprising the coated cathode material particles; (c) casting the slurry on a surface to form a layer; and (d) calendering the layer to form the cathode. In this embodiment, step (a) may further comprise exposing the cathode material particles to a boron-containing precursor followed by the oxygen-containing precursor to form the coating on the cathode material particles. Step (a) can occur at a temperature between 50° C. and 280° C. The method may further comprise: (e) placing a side of a separator in contact with the cathode; and (f) placing an opposite side of the separator in contact with an anode to form an electrochemical cell.

In this embodiment, the lithium-containing precursor can comprise a lithium alkoxide. The boron-containing precursor can comprise a boron alkoxide. The oxygen-containing precursor can be selected from the group consisting of ozone, water, oxygen plasma, ammonium hydroxide, oxygen, and mixtures thereof. The lithium-containing precursor, the boron-containing precursor, and the oxygen-containing precursor can be in a gaseous state. The cathode material particles can be selected from the group consisting of lithium metal oxides wherein the metal is one or more of aluminum, cobalt, iron, manganese, nickel, vanadium, and lithium-containing phosphates having a general formula LiMPO₄ wherein M is one or more of cobalt, iron, manganese, and nickel. The cathode material particles can be selected from the group consisting of cathode material particles having a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811).

In this embodiment, the coating can be a film having a thickness of 0.1 to 50 nanometers. In this embodiment, the coating can be a film having an ionic conductivity of greater than 1.0×10⁻⁷ S/cm. In this embodiment, the coating can be a film having an ionic transference number of greater than 0.9999 from 0-6 volts vs lithium metal. In this embodiment, the coating can be a film that is electrochemically stable at a Li+/Li⁰ redox potential or less. In this embodiment, the coating can be a film that increases wettability of a liquid electrolyte on the cathode material particles. In this embodiment, the coating can be a film that alters a solid electrolyte interphase that forms as a result of the cathode material particles interacting with an electrolyte relative to a reference solid electrolyte interphase that forms as a result of the cathode material particles having no film interacting with the electrolyte.

Another embodiment of the invention provides a method for forming an anode, wherein the method comprises: (a) exposing anode material particles to a lithium-containing precursor followed by an oxygen-containing precursor to form a coating on the anode material particles; (b) forming a slurry comprising the coated anode material particles; (c) casting the slurry on a surface to form a layer; and (d) calendering the layer to form the anode. In this embodiment, step (a) may further comprise exposing the anode material particles to a boron-containing precursor followed by the oxygen-containing precursor to form the coating on the anode material particles. Step (a) can occur at a temperature between 50° C. and 280° C. The method can further comprise: (e) placing a side of a separator in contact with the anode; and (f) placing an opposite side of the separator in contact with a cathode to form an electrochemical cell.

In this embodiment, the lithium-containing precursor can comprise a lithium alkoxide. In this embodiment, the boron-containing precursor can comprise a boron alkoxide. In this embodiment, the oxygen-containing precursor can be selected from the group consisting of ozone, water, oxygen plasma, ammonium hydroxide, oxygen, and mixtures thereof. In this embodiment, the lithium-containing precursor, the boron-containing precursor, and the oxygen-containing precursor can be in a gaseous state.

In this embodiment, the anode material particles can be selected from the group consisting of graphite, soft carbon, hard carbon, silicon, silicon-carbon composites, lithium titanate (LTO), lithium metal, and mixtures thereof. In this embodiment, the anode material particles can comprise graphite.

In this embodiment, the coating can be a film having a thickness of 0.1 to 50 nanometers. In this embodiment, the coating can be a film having an ionic conductivity of greater than 1.0×10⁻⁷ S/cm. In this embodiment, the coating can be a film having an ionic transference number of greater than 0.9999 from 0-6 volts vs lithium metal. In this embodiment, the coating can be a film that is electrochemically stable at a Li+/Li⁰ redox potential or less. In this embodiment, the coating can be a film that increases wettability of a liquid electrolyte on the anode material particles. In this embodiment, the coating can be a film that alters a solid electrolyte interphase that forms as a result of the anode material particles interacting with an electrolyte relative to a reference solid electrolyte interphase that forms as a result of the anode material particles having no film interacting with the electrolyte.

Another embodiment of the invention provides a method for forming a cathode for an electrochemical device, wherein the method comprises: (a) forming a mixture comprising cathode material particles; (b) calendering the mixture such that a porous structure is formed; and (c) exposing the porous structure to a lithium-containing precursor followed by an oxygen-containing precursor to form a coating on the porous structure. Step (c) may further comprise exposing the porous structure to a boron-containing precursor followed by the oxygen-containing precursor to form the coating on the porous structure. Step (c) can occur at a temperature between 50° C. and 280° C. The method may further comprise: (d) placing a side of a separator in contact with the cathode; and (e) placing an opposite side of the separator in contact with an anode to form an electrochemical cell.

In this embodiment, the lithium-containing precursor comprises a lithium alkoxide. In this embodiment, the boron-containing precursor comprises a boron alkoxide. In this embodiment, the oxygen-containing precursor can be selected from the group consisting of ozone, water, oxygen plasma, ammonium hydroxide, oxygen, and mixtures thereof. In this embodiment, the lithium-containing precursor, the boron-containing precursor, and the oxygen-containing precursor can be in a gaseous state.

In this embodiment, the cathode material particles can be selected from the group consisting of lithium metal oxides wherein the metal is one or more of aluminum, cobalt, iron, manganese, nickel, vanadium, and lithium-containing phosphates having a general formula LiMPO₄ wherein M is one or more of cobalt, iron, manganese, and nickel. In this embodiment, the cathode material particles can be selected from the group consisting of cathode material particles having a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811).

In this embodiment, the coating can be a film having a thickness of 0.1 to 50 nanometers. In this embodiment, the coating can be a film having an ionic conductivity of greater than 1.0×10⁻⁷ S/cm. In this embodiment, the coating can be a film having an ionic transference number of greater than 09999 from 0-6 volts vs lithium metal. In this embodiment, the coating can be a film that is electrochemically stable at a Li⁺/LiF⁰ redox potential or less. In this embodiment, the coating can be a film that increases wettability of a liquid electrolyte on the cathode material particles. In this embodiment, the coating can be a film that alters a solid electrolyte interphase that forms as a result of the cathode material particles interacting with an electrolyte relative to a reference solid electrolyte interphase that forms as a result of the cathode material particles having no film interacting with the electrolyte.

Another embodiment of the invention provides a method for forming an anode for an electrochemical device, wherein the method comprises: (a) forming a mixture comprising anode material particles; (b) calendering the mixture such that a porous structure is formed; and (c) exposing the porous structure to a lithium-containing precursor followed by an oxygen-containing precursor to form a coating on the porous structure. Step (a) may further comprise exposing the porous structure to a boron-containing precursor followed by the oxygen-containing precursor to form the coating on the anode material particles. Step (c) can occur at a temperature between 50° C. and 280° C. The method may further comprise: (d) placing a side of a separator in contact with the anode; and (e) placing an opposite side of the separator in contact with a cathode to form an electrochemical cell.

In this embodiment, the lithium-containing precursor may comprise a lithium alkoxide. In this embodiment, the boron-containing precursor may comprise a boron alkoxide. In this embodiment, the oxygen-containing precursor can be selected from the group consisting of ozone, water, oxygen plasma, ammonium hydroxide, oxygen, and mixtures thereof. In this embodiment, the lithium-containing precursor, the boron-containing precursor, and the oxygen-containing precursor can be in a gaseous state. In this embodiment, the anode material particles can be selected from the group consisting of graphite, soft carbon, hard carbon, silicon, silicon-carbon composites, titanate (LTO), lithium metal, and mixtures thereof. In this embodiment, the anode material particles can comprise graphite.

In this embodiment, the coating can be a film having a thickness of 0.1 to 50 nanometers. In this embodiment, the coating can be a film having an ionic conductivity of greater than 1.0×10⁻⁷ S/cm. In this embodiment, the coating can be a film having an ionic transference number of greater than 0.9999 from 0-6 volts vs lithium metal. In this embodiment, the coating can be a film that is electrochemically stable at a Li⁺/Li⁰ redox potential or less. In this embodiment, the coating can be a film that increases wettability of a liquid electrolyte on the anode material particles. In this embodiment, the coating can be a film that alters a solid electrolyte interphase that forms as a result of the anode material particles interacting with an electrolyte relative to a reference solid electrolyte interphase that forms as a result of the anode material particles having no film interacting with the electrolyte.

Another embodiment of the invention provides a cathode for an electrochemical device, wherein the cathode comprises: cathode material particles selected from the group consisting of lithium metal oxides wherein the metal is one or more of aluminum, cobalt, iron, manganese, nickel, vanadium, and lithium-containing phosphates having a general formula LiMPO₄ wherein M is one or more of cobalt, iron, manganese, and nickel; and a nanoscale film on at least a portion of a surface of the cathode material particles, the film comprising a lithium borate-based material, or a lithium carbonate based material or a mixture thereof. In this embodiment, the cathode material particles can be selected from the group consisting of cathode material particles having a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811). The cathode may further comprise: a separator in contact with the cathode; and an anode in contact with an opposite side of the separator to form an electrochemical cell.

In this embodiment, the film can comprise Li₃BP₃—Li₂CO₃. In this embodiment, the film can have a thickness of 0.1 to 50 nanometers. In this embodiment, the film can have an ionic conductivity of greater than 1.0×10⁻⁷ S/cm. In this embodiment, the film can have an ionic transference number of greater than 0.9999 from 0-6 volts vs lithium metal. In this embodiment, the film can be electrochemically stable at a Li⁺/Li₀ redox potential or less. In this embodiment, the film can increase wettability of a liquid electrolyte on the cathode material particles. In this embodiment, the film can alter a solid electrolyte interphase that forms as a result of the cathode material particles interacting with an electrolyte relative to a reference solid electrolyte interphase that forms as a result of the cathode material particles having no film interacting with the electrolyte.

Another embodiment of the invention provides an anode for an electrochemical device, wherein the anode comprises: anode material particles selected from the group consisting of graphite, soft carbon, hard carbon, silicon, silicon-carbon composites, lithium titanate (LTO), lithium metal, and mixtures thereof; and a nanoscale film on at least a portion of a surface of the anode material particles, the film comprising a lithium borate-based material, or a lithium carbonate based material or a mixture thereof. In this embodiment, the anode can further comprise: a separator in contact with the anode; and a cathode in contact with an opposite side of the separator to form an electrochemical cell.

In this embodiment, the film can comprise Li₃BO₃—Li₂CO₃. In this embodiment, the film can have a thickness of 0.1 to 50 nanometers. In this embodiment, the film can have an ionic conductivity of greater than 1.0×10⁻⁷ S/cm. In this embodiment, the film can have an ionic transference number of greater than 09999 from 0-6 volts vs lithium metal. In this embodiment, the film can be electrochemically stable at a Li⁺/Li⁰ redox potential or less. In this embodiment, the anode material particles can comprise graphite.

In this embodiment, the film can increase wettability of a liquid electrolyte on the anode material particles. In this embodiment, the film can alter a solid electrolyte interphase that forms as a result of the anode material particles interacting with an electrolyte relative to a reference solid electrolyte interphase that forms as a result of the anode material particles having no film interacting with the electrolyte.

One embodiment described herein relates to a method for creating a lithium-ion-battery using atomic layer deposition (ALD). The lithium-ion battery can be a solid-state-battery or a liquid-electrolyte-based lithium-ion battery.

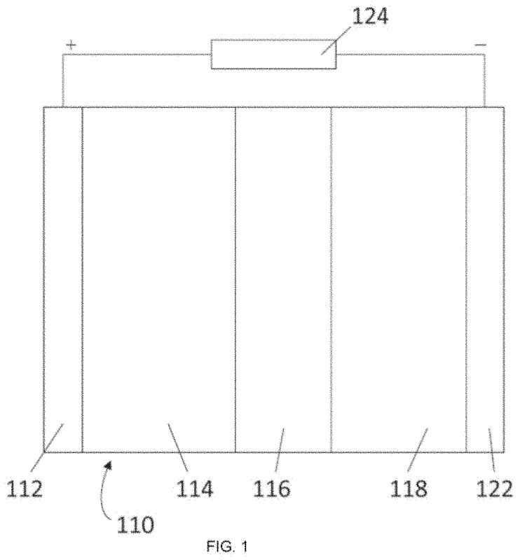

In one non-limiting example application, atomic layer deposition can be used in forming a thin film lithium battery 110 as depicted in FIG. 1. The thin film lithium battery 110 includes a current collector 112 (e.g., aluminum) in contact with a cathode 114. The separator 116 is arranged between the cathode 114 and an anode 118, which is in contact with a current collector 122 (e.g., aluminum). The current collectors 112 and 122 of the thin film lithium battery 110 may be in electrical communication with an electrical component 124. The electrical component 124 could place the thin film lithium battery 110 in electrical communication with an electrical load that discharges the battery or a charger that charges the battery.

The electrolyte for the battery 110 may be a liquid electrolyte. The liquid electrolyte of the electrochemical cell may comprise a lithium compound in an organic solvent. The lithium compound may be selected from LiPF₆, LiBF₄, LiClO₄, lithium bis(fluorosulfonyl)imide (LiFSI), LiN(CF₃SO₂)₂ (LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent is selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

The first current collector 112 and the second current collector 122 can comprise a conductive metal or any suitable conductive material. In some embodiments, the first current collector 112 and the second current collector 122 comprise aluminum, nickel, copper, combinations and alloys thereof. In other embodiments, the first current collector 112 and the second current collector 122 have a thickness of 0.1 microns or greater. It is to be appreciated that the thicknesses depicted in FIG. 1 are not drawn to scale, and that the thickness of the first current collector 112 and the second current collector 122 may be different.

A suitable active material for the cathode 114 of the thin film lithium battery 110 is a lithium host material capable of storing and subsequently releasing lithium ions. An example cathode active material is a lithium metal oxide wherein the metal is one or more aluminum, cobalt, iron, manganese, nickel and vanadium. Non-limiting example lithium metal oxides are LiCoO₂ (LCO), LiFeO₂, LiMnO₂ (LMO), LiMn₂O₄, LiNiO₂ (LNC)), LiNiₓCo_{y}O₂, LiMnₓCo_{y}O₂, LiMnₓNi_{y}O₂, LiMnₓNi_{y}O₄, LiNiₓCo_{y}Al_{z}O₂, LiNi_{1/3}Mn_{1/3}Co_{1/3}O₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. Another example of a cathode active material is V₂O₅. Many different elements, e.g., Co, Mn, Ni, Cr, Al, or Li, may be substituted or additionally added into the structure to influence electronic conductivity, ordering of the layer, stability on delithiation and cycling performance of the cathode materials. The cathode active material can be selected from the group consisting of cathode material particles having a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811). The cathode active material can be a mixture of any number of these cathode active materials. In other embodiments, a suitable material for the cathode 114 of the thin film lithium battery 110 is porous carbon (for a lithium air battery), or a sulfur containing material (for a lithium sulfur battery).

In some embodiments, a suitable active material for the anode 118 of the thin film lithium battery 110 consists of lithium metal. In other embodiments, an example anode 118 material consists essentially of lithium metal. Alternatively, a suitable anode 118 consists essentially of magnesium, sodium, or zinc metal. Alternatively, a suitable anode 118 comprises a material selected from graphite, lithium titanate, hard carbon, tin/cobalt alloy, silicon, and silicon-carbon composites. Alternatively, a suitable anode 118 comprises a conversion-type anode material such as a transition-metal oxide, a transition-metal sulfide, or a transition-metal phosphide.

The thin film lithium battery 110 comprises a separator 116 located between the cathode 114 and the anode 118. An example separator 116 material for the thin film lithium battery 110 can a permeable polymer such as a polyolefin. Example polyolefins include polyethylene, polypropylene, and combinations thereof. The separator 116 may have a thickness in the range of 1 to 200 nanometers, or in the range of 40 to 1000 nanometers.

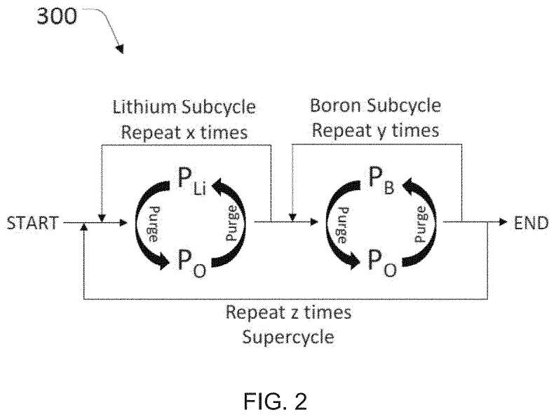

FIG. 2 depicts a process flowchart 300 for a method of making an ionically conductive film using an atomic layer deposition process of the present invention. The method can comprise a first step in which a substrate is exposed to a lithium-containing precursor, which reacts with the surface and the excess and product species are removed from the surface. Subsequently, an oxygen-containing precursor is exposed to the surface, and another reaction occurs. This represents single “subcycle”, which can be repeated x times, where x may be any integer from 1 to 10. Then another subcycle where a boron-containing precursor is exposed to the substrate followed by an oxygen-containing precursor can be repeated y times, where y may be any integer from 1 to 10. This entire “supercycle” can then be repeated z times to deposit a layer of the desired thickness. The value of z may be an integer between 1 and 5000, between 10 and 1000, or between 100 and 500. This process may result in the formation of a film comprising lithium, boron, and oxygen, and in some cases carbon. The precursors may be in a gaseous state. The subcycles may occur in either order to start the supercycle.

The sequential reactions can be separated either chronologically or spatially.

The lithium-containing precursor may be selected from the group consisting of lithium tert-butoxide (LiO^{t}Bu), 2,2,6,6-tetramethyl-3,5-heptanedionate (Li(thd)), and lithium hexamethyldisilazide (LiHMDS). The lithium-containing precursor may be a lithium alkoxide such as lithium tert-butoxide. The boron-containing precursor may be selected from the group consisting of triisopropylborate (TIB), boron tribromide (BBr₃), boron trichloride (BCl₃), triethylboron (TEB), tris(ethyl-methylamino) borane, trichloroborazine (TCB), tris(dimethylamido)borane (TDMAB); trimethylborate (TMB), diboron tetrafluoride (B₂F₄). The boron-containing precursor may be a boron alkoxide such as triisopropylborate. The oxygen-containing precursor may be selected from the group consisting of ozone (O₃), water (H₂O), oxygen plasma (O₂(p)), ammonium hydroxide (NH₄OH), Oxygen (O₂). The oxygen-containing precursor may be ozone.

The film formed by the method 300 may have a thickness between 20 and 100 nanometers, between 0.1 and 1000 nanometers, between 1 and 100 nanometers, between 20 and 80 nanometers, or between 0.1 and 50 nanometers, or between 0.1 and 35 nanometers. The ionically conductive film layer may have a total area specific-resistance (ASR) of less than 450 ohm cm², or is less than 400 ohm cm², or is less than 350 ohm cm², or is less than 300 ohm cm², or is less than 250 ohm cm², or is less than 200 ohm cm², or is less than 150 ohm cm², or is less than 100 ohm cm², or is less than 75 ohm cm², or is less than 50 ohm cm², or is less than 25 ohm cm², or is less than 10 ohm cm², or less than 5 Ω-cm².

The film formed by the method 300 may have an ionic conductivity of greater than 1.0×10⁻⁷ S/cm, or greater than 1.0×10⁻⁶ S/cm, or greater than 1.5×10⁻⁶ S/cm, or greater than 2.0×10⁻⁶ &cm, or greater than 2.2×10⁻⁶ S/cm at standard temperature and pressure. The ionically conductive layer may have an ionic transference number of greater than 0.9999 from 0-6 volts vs lithium metal. The first step and second step may occur in any order and at a temperature between 50° C. and 280° C., or between 180° C. and 280° C., or between 200° C. and 220° C.

The substrate of the method of 300 can be an anode or a cathode. The substrate of the method of 300 can be planar or have a three dimensional structure, such as a corrugated structure.

Forming An Electrode For An Electrochemical Device

The present disclosure relates to forming an electrode for use in an electrochemical device, such as a lithium ion battery or a lithium metal battery. In one embodiment, the method for forming an electrode includes depositing a film of the present disclosure on a powdered electrode material, and forming a slurry comprising the coated electrode material. The slurry is then cast on a surface to form a layer, and the layer is dried and calendered to form the electrode. The electrode material may be any of the anode materials or cathode materials described above.

In another embodiment, the electrode may be produced by forming a slurry comprising an electrode material, casting the slurry on a surface to form a layer, and drying and calendering the layer. A film of the present disclosure is then deposited on a surface of the dried and calendered layer to form a thin film to complete forming the electrode.

In another embodiment, the electrode may be produced by forming a slurry comprising an electrode material, casting the slurry on a surface to form a layer, calendering the layer, and depositing a film of the present disclosure on the layer. The film coated layer is then dried and calendered to complete forming the electrode.

The slurry as described in any of the preceding embodiments may be formed by mixing the electrode material or coated electrode material with an aqueous or organic solvent. Suitable solvents may include N-methyl-2-pyrrolidone (NMP) or other suitable alternatives that would be readily understood to those skilled in the art. A binder may also be added to the slurry, such as polyvinylidene fluoride (PVDF) or any suitable alternative that would be readily understood to those skilled in the art. A conductive additive, such as a metallic powder or carbon black, may also be added to the slurry.

The layer of the electrode as discussed in any of the preceding embodiments may be dried and calendered to have a thickness that ranges between 1 to 200 microns. In some embodiments, the thickness of the electrode is less than 175 microns, or less than 150 microns, or less than 125 microns, or less than 100 microns, or less than 75 microns, or less than 50 microns.

The thin film coating on the surfaces of the electrode material as discussed in any of the preceding embodiments may have a thickness that ranges from 0.1 to 50 nanometers, One example thin film coating comprises Li₃BO₃—Li₂CO₃.

### EXAMPLES

The following Examples are provided in order to demonstrate and further illustrate certain embodiments and aspects of the present invention and are not to be construed as limiting the scope of the invention. The statements provided in the examples are presented without being bound by theory.

### Example 1

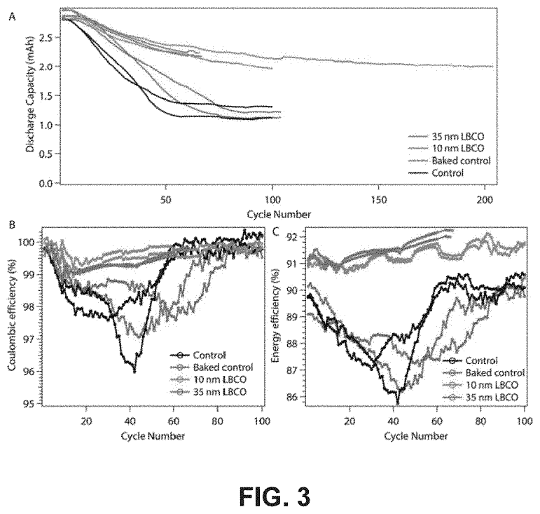

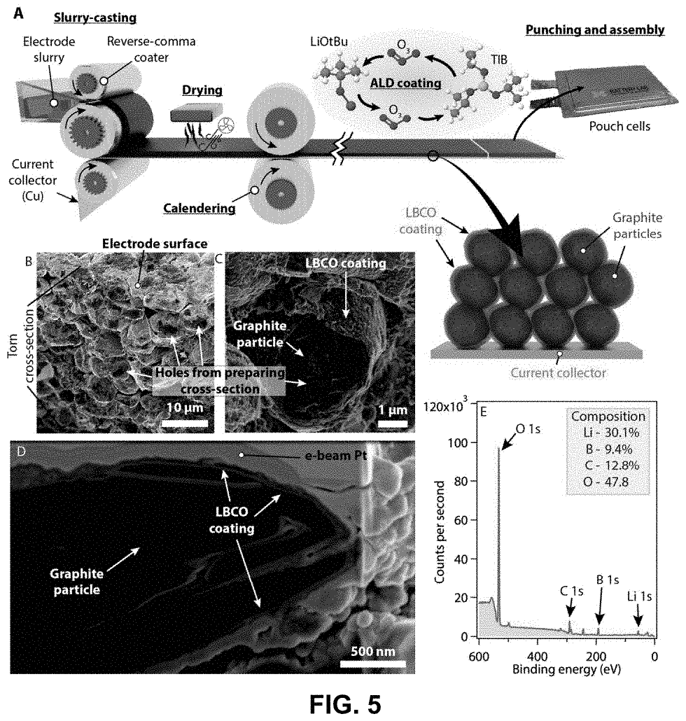

Cells with LBCO-coated graphite electrodes have exhibited improved Coulombic efficiency, decreased interfacial impedance, decreased cell polarization, improved rate capability, improved cycle life, and dramatically reduced Li plating. Examples of the improvements in cycle performance, efficiency, cell polarization, and Li plating are shown in FIGS. 3-5. In (B) of FIG. 5, it is evident that both the 10 nm and 35 nm LBCO coatings improve the capacity retention compared to the control and the baked control, which was exposed to the temperature and vacuum of the ALD reactor without any deposition. In addition to the improved capacity retention, both the Coulombic and energy efficiencies of the cells are improved as well. More specifically, the large drop in efficiency during approximately the first 40 cycles is suppressed. As this drop has been attributed to Li plating on the graphite electrode, this indicates that this plating has been suppressed.

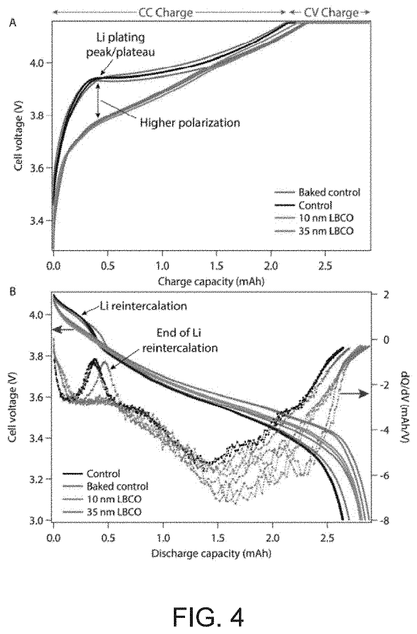

This is confirmed by examination of the charge and discharge profiles in cycle 10 of the 4C cycling, as shown in FIG. 4. In (A) of FIG. 4, the control and baked control exhibit a larger polarization compared to the cells with LBCO coated graphite, and a characteristic peak and plateau associated with plating of metallic Li on the graphite electrode. The decreased Li plating on the LBCO coated electrodes is corroborated by the absence of the Li reintercalation feature in the beginning of the discharge profile and the corresponding peak in the dQ/dV curve.

The proposed mechanism of these improvements is related to one or more of the following factors: (1) improved wettability of the liquid electrolyte on the electrode surface, enabling improved transport of Li ions into the electrode, reducing concentration gradients, (2) the LBCO film serves as an artificial solid electrolyte interphase (SEI), which reduces the amount of Li consumed in the first charging cycle, reduces the impedance of the SEI, and improves interfacial kinetics, (3) reducing the wettability of Li metal on the electrode surface, increasing the overpotential required to nucleate Li plating.

The demonstrated improvements in performance make this a promising strategy for improving rate capability and capacity retention of lithium-ion batteries for applications such as electric vehicles. As ALD has been scaled-up for roll-to-roll processing for other applications, and is already being used to coat lithium ion battery electrodes with other materials, it is possible to scale-up this technique. The treatment can enable faster charging for a given electrode loading (as shown), or enable the use of thicker electrodes with higher loading, both of which are of great interest to commercial applications.

### Example 2

Overview of Example 2

Enabling fast-charging (≥4C) of lithium-ion batteries is an important challenge to accelerate the adoption of electric vehicles. However, the desire to maximize energy density has driven the use of increasingly thick electrodes, which hinders power density. Herein, atomic layer deposition was used to coat a single-ion conducting solid electrolyte (Li₃BO₃—Li₂CO₃) onto post-calendered graphite electrodes, forming an artificial solid-electrolyte interphase (SEI). When compared to uncoated control electrodes, the solid electrolyte coating: (1) eliminates natural SEI formation during preconditioning; (2) decreases interphase impedance by >75% compared to the natural SEI; and (3) extends cycle life 40-fold under 4C charging conditions, enabling retention of 80% capacity after 500 cycles in pouch cells with >3 mAh-cm⁻² loading. Example 2 demonstrates that 4C charging without Li plating can be achieved through purely interfacial modification without sacrificing energy density, and sheds new light on the role of the SEI in Li plating and fast-charge performance.

1. Introduction to Example 2

Lithium-ion batteries (LIBs) have become a vital part of the way that society stores and uses electrical energy. Among the myriad applications, electric vehicles (EVs) are rapidly becoming the dominant source of demand for rechargeable batteries. [Ref. 1] Despite significant advances over the past several years, further improvements in energy density, charging rate, and cycle life remain key challenges. [Ref. 2] In particular, achieving all of these characteristics simultaneously is elusive.

Tradeoffs arise between energy density, charging rate, and cycle life when thicker (higher areal capacity) electrodes are used. [Ref. 3] This has been largely attributed to mass-transport limitations in the electrolyte within the porous electrode structures, which lead to increased cell polarization, current focusing, and inhomogeneous lithiation, [Refs. 4.5] As a result, metallic Li can plate out on the electrode surface under fast-charging conditions in high-energy-density cells. The irreversibility associated with Li plating leads to permanent loss of Li from the accessible reservoir and capacity fade, which is the key challenge that limits fast-charging of LIBs.

Therefore, strategies to prevent and/or mitigate the impacts of Li plating on graphite have drawn great interest in recent years, including; (1) alternative anode materials such as lithium titanate, [Ref. 6] titanium niobate, [Ref. 7] and hybrid mixtures of hard carbon with graphite; [Ref. 5] (2) modifying the electrode architecture to facilitate enhanced mass transport; [Refs. 8-12] (3) asymmetric temperature modulation; [Ref. 13] (4) surface coatings to modify interface behavior; [Ref. 14-17] and (5) electrolyte modifications to increase ionic conductivity. [Refs. 18-20] To date, a majority of work on fast charging of graphite aims to homogenize the current distribution throughout the electrode thickness by improving mass transport in the electrolyte.

While these works have shown great promise for enabling fast charging and have demonstrated the importance of mass transport, less attention has been paid to the role of the solid-electrolyte interphase (SEI) in determining fast-charge performance. In state-of-the-art LIBs, a mosaic SEI consisting of inorganic and organic species forms naturally during the initial charge due to electrolyte decomposition as the graphite electrode potential drops towards the equilibrium potential of Li metal (−3.04 V vs. SHE). [Refs. 21-23] The primary means of engineering the SEI has been through electrolyte modifications, which has proven to be a key enabler for the high Coulombic efficiency and long cycle-life of today's LIBs. [Ref. 24] The properties of the natural SEI are sufficient at low current densities, when the electrochemical potential remains >0 V vs. Li/Li⁺, but do not prevent Li plating during fast-charging.

While artificial SEI (a-SEI) coatings have been studied to improve interfacial stability, less attention has been paid to optimization of a-SEIs for fast charging. Our hypothesis in this work of Example 2 is that an ideal a-SEI for fast charging would: (1) have higher ionic conductivity than the natural SEI and low electronic conductivity; (2) be chemically homogenous, avoiding “hot-spots” within the SEI such as grain boundaries, local variations in composition and phase, etc.; (3) be electrochemically stable both in contact with the liquid electrolyte and with Li metal, such that decomposition reactions do not occur even below 0 V vs. Li/Li⁺; and (4) suppress both natural SEI formation and Li plating.

Fortunately, there has been a great deal of recent work to understand both solid electrolyte materials that are stable in contact with Li metal, [Ref. 25] and nucleation behavior in Li metal anodes. [Ref. 26] We have recently developed atomic layer deposition (ALD) processes for single-ion conducting solid electrolytes that are stable against Li. [Refs. 27-28] In particular, ALD of glassy Li₃BO₃—Li₂CO₃ (LBCO) solid electrolytes have shown to exhibit the properties listed above. LBCO films were shown to have the highest measured ionic conductivity of any ALD film reported to date (>2*10⁻⁶ S/cm at 30° C.), and are stable when cycled in contact with Li metal. [Ref. 29]

ALD affords unparalleled control of film thickness and conformality owing to the self-limiting nature of the surface reactions. [Ref. 30] ALD is a powerful means of interface modification for electrode materials in LIBs, [Refs. 31-40] but work to date has largely focused on coating cathodes to improve interface stability. [Refs. 41-43] Reports of coatings on graphite have been limited to Al₂O₃[Refs. 31,32,34,44] and TiO₂, [Refs. 33,44] and have generally been extremely thin, often less than 1 nm. This is due to the fact that these oxide materials are relatively poor ionic conductors, even after they are electrochemically lithiated, which consumes Li. [Ref. 45]

Instead of relying on in situ lithiation of a binary oxide, herein we demonstrate the use of a single-ion conducting solid electrolyte (LBCO) coating on graphite. The conformal ALD coating is shown to eliminate natural SEI formation, resulting in a 75% decrease in interphase impedance. Cells with coated electrodes exhibit superior rate capability and stability during fast charging. The cycle life to 80% capacity retention under 15 min. (4C) fast-charging conditions was increased more than 40-fold (to >500 cycles) compared to uncoated control cells. This is primarily attributed to the suppression of Li plating. In addition to demonstrating a new strategy to overcome energy power density tradeoffs, this work of Example 2 points to the key role of the SEI and its associated impedance in limiting the fast-charge capability of LIBs.

### 2. Results and Discussion

2.1. Demonstration of ALD LBCO on Graphite Electrodes

Graphite electrodes were prepared on a pilot-scale roll-to-roll slurry-casting system at the University of Michigan Battery Manufacturing Lab via the process shown in (A) of FIG. 5 (further details in Experimental methods), [Refs. 5,9] To demonstrate that the LBCO ALD process could successfully coat post-calendered graphite electrodes, x-ray photoelectron spectroscopy (XPS) and scanning electron microscopy (SEM) were performed after the coating process. FIG. 5 in (B) shows an XPS survey scan of a graphite electrode surface coated with 250 ALD supercycles of LBCO (˜20 nm). One supercycle consists of sequential exposures of lithium Cert-butoxide, ozone, triisopropylborate, and ozone, each separated by purging, as described previously. [Ref. 29] This will be termed LBCO 250x throughout Example 2, and other thicknesses will be described similarly based on the number of ALD cycles. As expected for the LBCO coating, the surface is composed of lithium, carbon, boron, and oxygen, [Ref. 29]

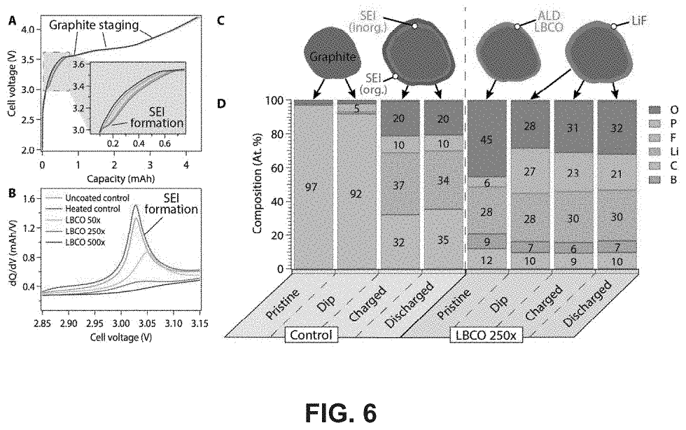

In addition, SEM imaging was performed on an LBCO-coated electrode to observe the morphology and conformality of the ALD coating. As shown in (C) of FIG. 5, the presence of a surface coating can clearly be observed, along with the exposed regions of the electrode that resulted from tearing of the electrode to prepare the cross-section. While the entire surface of the electrode particles was conformally coated, when the electrode was torn to create a cross-section, the contact points between adjacent graphite particles resulted in these exposed regions. These point contacts show that the particle-particle contacts formed during the calendaring process are maintained after coating, preserving electrical continuity throughout the electrode. The conformality of the film through the full thickness of the electrode, and the electrochemical results shown in FIG. 6, confirm that the ALD process successfully coated the entire electrode.

A high-magnification image of a focused-ion beam (FIB) cross-section is shown in (D) of FIG. 5, The film is ˜40 nm thick, as expected for the 500x coating, and conformally coats along the entire surface of the graphite particle, including re-entrant surface geometries and the bottom surface that would be shadowed when using line-of-sight deposition methods. This type of conformal coating with precisely controllable thickness would be challenging to achieve with other coating techniques, demonstrating the unique properties of ALD for coating of porous materials.

To investigate any physical changes to the electrodes that might have been caused by the elevated temperatures or vacuum conditions during the ALD process, the thickness and mass of multiple control (no exposure to the ALD chamber), heated control, and LBCO 250x coated electrodes were measured. The heated control was exposed to the temperature and pressure conditions of the ALD reactor for the same length of time as the 250x process. A table of the resulting measurements is shown in Table 1, which indicates that the total thickness of the calendared graphite electrodes increased by approximately 4-8% due to the ALD temperature and pressure conditions. To identify any potential effects from these slight structural changes on the observed electrochemical behavior, we also examine the performance of the heated control without ALD coating below.

2.2. Suppression of SEI Formation During Preconditioning

Graphite electrodes (3.18 mAh-cm⁻² loading, details in Experimental Methods) were prepared with varying numbers of ALD cycles (50x, 250x, and 500x corresponding to 4, 20, and 40 nm) to investigate the impact of the ALD coating on cell performance and identify the optimum thickness. These electrodes were assembled into coin cells with NMC532 cathodes for testing (details in Experimental Methods). After assembly, the cells were preconditioned with (3) C/10 constant current (CC) cycles, the first of which is shown in (A) of FIG. 6. The first plateau in the first charge (observed at ˜3.0 volts) is associated with the initial SEI that forms on the graphite surface as the potential of the electrode drops below the reductive stability limit of the electrolyte. [Refs. 24,46] This plateau, which appears as a peak in the dQ/dV plot ((B) in FIG. 6), decreases with increasing thickness of LBCO coating. The plateau is almost completely suppressed in the 250x sample, and is absent in the 500x sample. This indicates that when the LBCO coating is sufficiently thick, it passivates the surface of the graphite and prevents reductive side-reactions with the salt and solvents that lead to SEI formation and growth.

Further insights into these differences in the SEI formation process were acquired via XPS analysis of both the control and 250x electrodes at various stages of formation: (1) pristine; (2) dipped in electrolyte; (3) after charging to 4.2V (charged); and (4) after one full cycle (discharged). These data, shown in (D) of FIG. 6, show substantial differences in the surface chemistry as the formation cycle proceeds. The pristine control electrode is comprised almost entirely of carbon, while the 250x coating closely resembles the LBCO film composition. A small amount of adventitious fluorine is present, which results from exposure to electrolyte vapors.

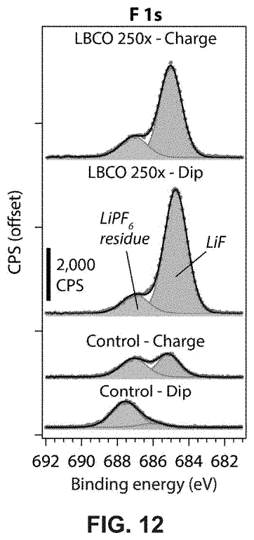

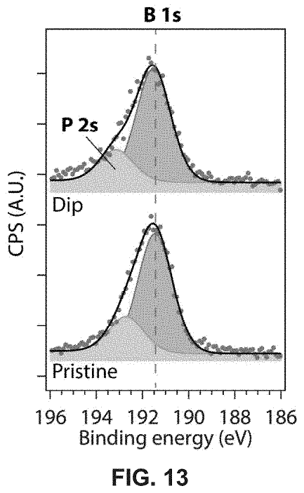

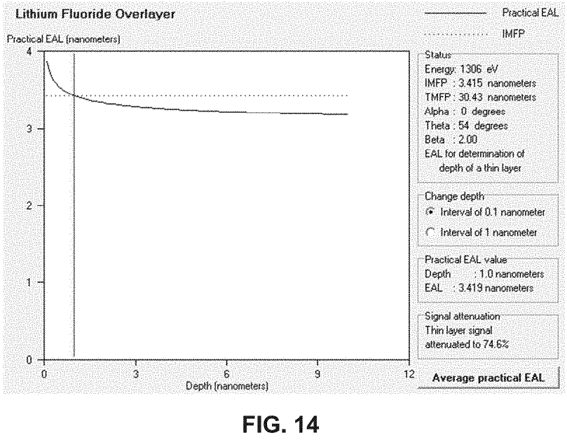

After submersing the electrode in the liquid electrolyte for 30 minutes and rinsing with dimethyl carbonate (DMC), the control electrode was still comprised of >90% carbon, with a modest increase in the amount of fluorine present. Examination of the F 1s core scan (FIG. 12), reveals that this F content arises from residual LiPF₆ salt, rather than a reacted interphase. In contrast, the 250x LBCO electrode exhibited a greater increase in F content, most of which was LiF in character based on the core scans. This indicates that the LBCO ALD film chemically reacts with the ions in the electrolyte under open circuit conditions. In the future, computational studies would be valuable to further elucidate this mechanism. Notably, the resulting surface did not increase in C content after the electrolyte exposure, suggesting that solvent decomposition does not occur on the LBCO surface. Furthermore, the B content only slightly decreases, and does not experience a chemical shift (FIG. 13). This demonstrates that the thickness of the LiF layer is significantly less than the escape depth of the photoelectrons emitted from LBCO, which is consistent with the formation of an extremely thin layer of LiF on the surface of the LBCO coating ((C) in FIG. 6), An approximate thickness of 1 nm was calculated based on the observed 20% decrease in signal of the B 1s electrons using the Electron Effective-Attenuation Length Calculator from the National Institute of Standards and Technology (FIG. 14). [Ref. 47] Therefore, the single-ion conducting LBCO coating is maintained, and serves as an a-SEI.

Following the first C/10 charging half-cycle, the 250x LBCO electrode surface composition was nearly identical to the dipped sample, while the control electrode changed dramatically. The carbon content of the control decreased from 92% to 32%, while the Li content increased from nearly zero to 37%, the O increased from near zero to 20%, and the F increased from 5% to 10%. These changes are consistent with the natural SEI formation that forms as the potential of the graphite electrode is decreased below the reductive stability window of the electrolyte during lithiation. [Ref. 46] After discharging the cell, neither the control or the 250x LBCO electrode exhibited substantial changes, although the control did decrease in Li content slightly.

The improved electrochemical stability of the 250x LBCO electrode compared to the control is consistent with the voltage curve analysis in (A) and (B) of FIG. 6. This is also consistent with cyclic voltammetry data for ALD LBCO, which do not show reductive currents as the electrode potential is decreased within the range of natural SEI formation. [Ref. 29] This illustrates the benefits of using a solid-state electrolyte with a wide electrochemical stability window to provide several of the properties of an ideal a-SEI.

2.3. Improved Fast-Charging Performance

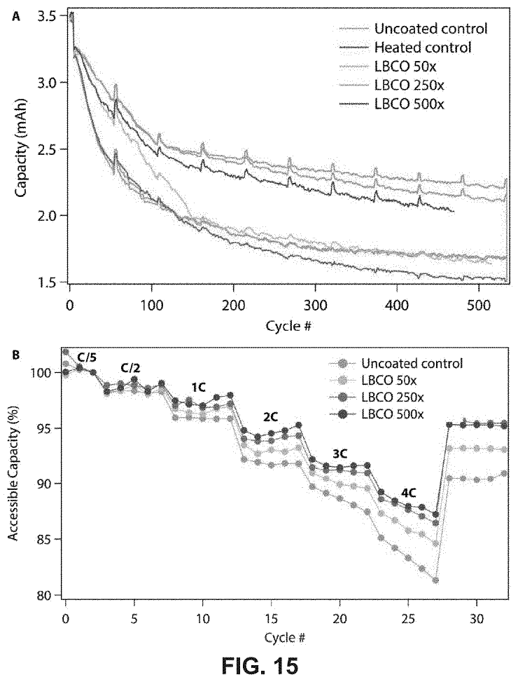

To identify the impact of LBCO a-SEI thickness on cycling performance and fast-charging capability, coin cells were subjected to various charging rates and extended cycling at a 4C rate (Further details in Supplementary Information, FIG. 15). The 250x coating had the best performance in terms of capacity retention, and thus was selected as the optimum coating thickness for further study.

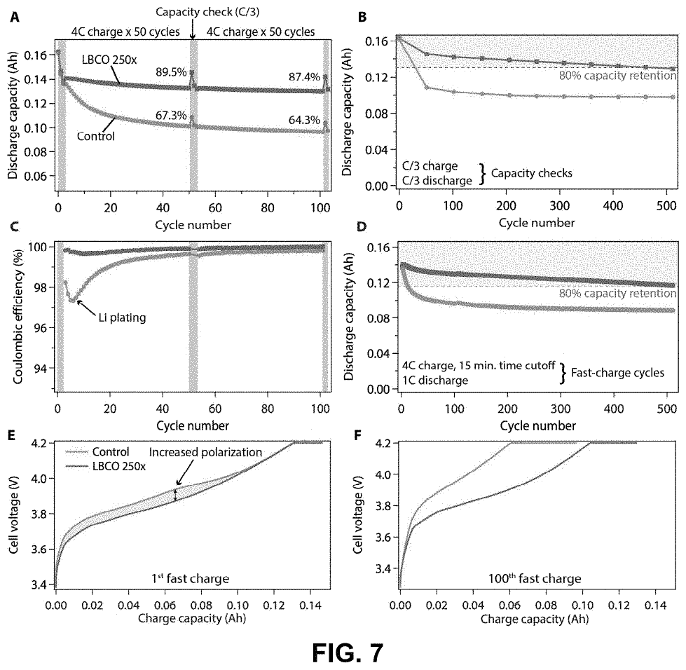

To investigate cell performance in a more industrially-relevant format, single-layer pouch cells (70 cm² electrodes) were fabricated for the control and the optimal 250x LBCO coating. Extended cycling with 4C fast charging was performed, following the U.S. Department of Energy test protocol for fast charging. [Refs. 5,48] The accessible capacity at low charge rate was also checked every 50 cycles. As shown in FIG. 7, the control cells exhibit rapid capacity fading in the first 10-20 cycles before reaching a more stable aging condition. The rapid capacity fade in the initial cycles of the control corresponds to a dip in the Coulombic efficiency (CE), which has been shown to be a result of Li plating. [Ref. 9] As a result, the capacity retention at C/3 is 67.3% after 50 4C-charge cycles. In contrast, the CE of the LBCO 250x cell is consistently higher than the control, and does not exhibit the initial dip in CE. The LBCO 250x cell exhibits much less capacity fade, retaining 89.5% of the original capacity to 50 cycles, and 79.4% after 500 cycles ((B) in FIG. 7).

The plot in (D) of FIG. 7 shows only the cycles with 4C fast-charging (without the capacity checks). Compared to the accessible capacity of the initial 4C charge cycle, the control cell fades to 80% capacity after only 12 cycles. In comparison, the LBCO 250x retains more than 80% throughout the 500-cycle test. This represents a greater than 40-fold increase in cycle life.

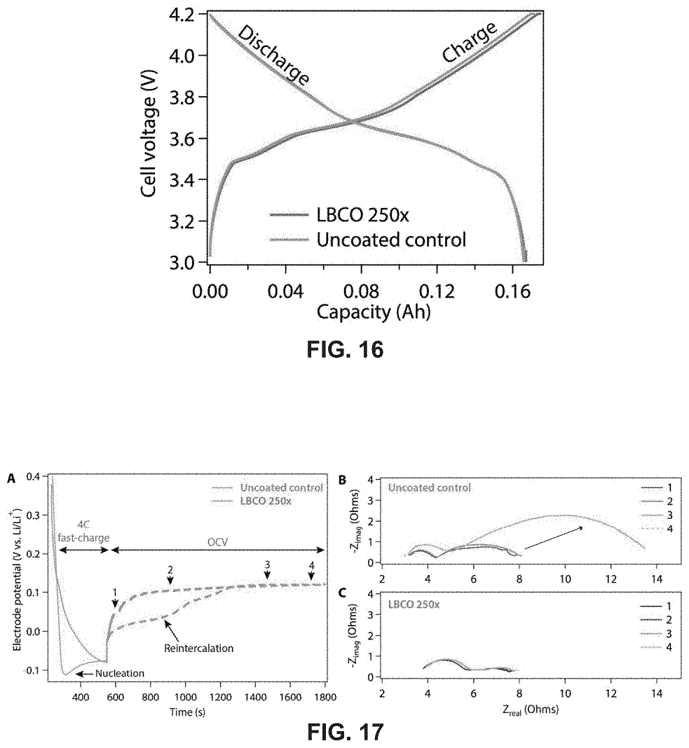

Further insight can be gained by examining the charge curves for the 1^{st} and 100^{th} fast-charge cycles, shown in (E) and (F) of FIG. 7, respectively. During the first 4C charge, the control electrode exhibits a higher cell voltage, and this remains the case throughout cycling. As shown in FIG. 16, the voltage traces at C/10 are nearly identical. Therefore, the higher cell voltage in the control is a result of larger polarization under fast-charge conditions. This indicates that the LBCO coating reduces the cell impedance, which is analyzed in detail in the following section. After 100 cycles ((F) in FIG. 7), the capacity of the control cell has faded dramatically, and the cell voltage quickly hits the 4.2 V cutoff. The LBCO 250x takes longer to reach the voltage cutoff, and retains a larger fraction of the initial capacity.

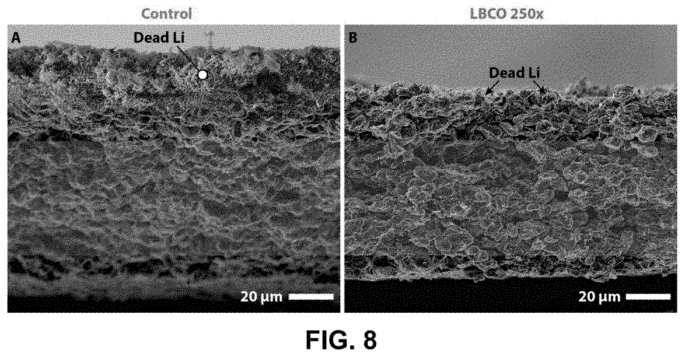

To confirm that the initial capacity fade in the control was a result of Li plating, pouch cells were disassembled after 100 fast-charge cycles. As shown in (A) in FIG. 8, cross-sectional SEM images reveal a 20-30 μm thick layer of dead Li on the control electrode. In contrast, the LBCO-coated electrode in (B) in FIG. 8 exhibits only trace amounts of dead Li. The dead Li is formed due to irreversible stripping and re-intercalation of Li metal that nucleated and grew on the graphite surface, [Ref, 49] This irreversibility depletes Li from the active reservoir, resulting in the capacity fading observed in FIG. 7. In addition, the tortuous dead Li layer further impedes the mass transport in the cell during fast-charging and decreases rate performance. [Ref. 50]

2.4. SEI Impedance and the Role in Fast Charging

The results from these pouch cells demonstrate that coating of graphite with a single-ion conducting solid electrolyte with a wide electrochemical stability window as an a-SEI is a viable means to improve capacity retention under fast-charge conditions, To investigate the properties of the a-SEI further, we characterized the frequency-dependent impedance of the control and 250x LBCO electrodes using electrochemical impedance spectroscopy (EIS). EIS analysis was performed in a 3-electrode cell using a Li-metal reference electrode (further details in Experimental Methods). This enables us to deconvolute the contributions of each electrode to the total impedance. Since the impedance of various processes within LIBs is known to change significantly as a function of state-of-charge (SOC), [Refs. 51,52] we collected impedance spectra at several points during charging of the cells.

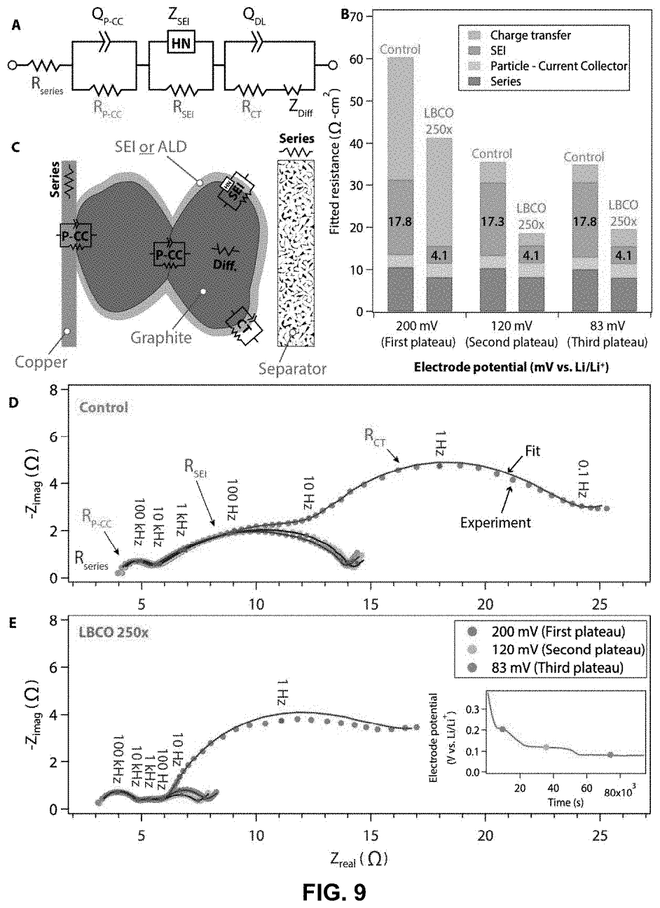

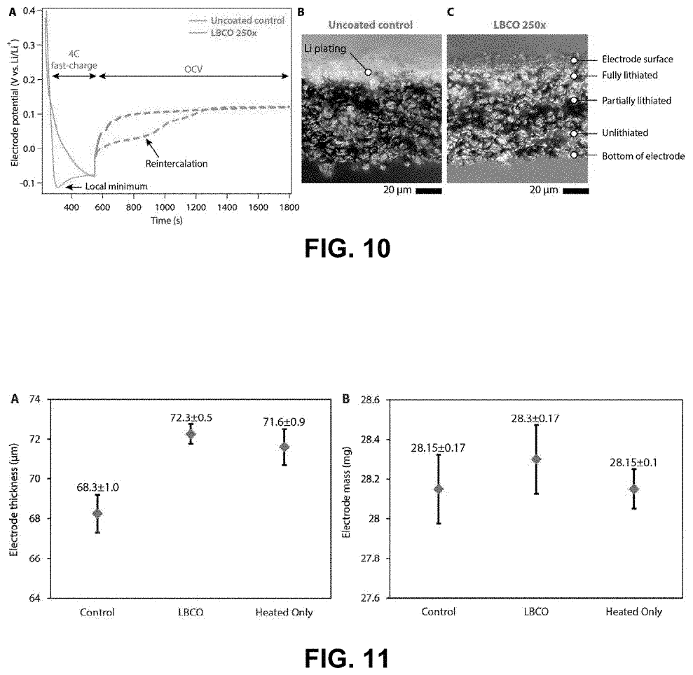

Contributions to the electrode impedance associated with distinct frequency responses were decoupled by fitting the spectra with the equivalent circuit model shown in (D) of FIG. 9. While there are numerous equivalent circuit models that have been implemented to fit LIB impedance spectra, the general processes/features included are fairly consistent (further details in Supplementary Information). [Ref. 53]

The results, shown in FIG. 9, exhibit some similarities between the control and LBCO 250x coated electrodes, but other key differences. Full details of the fitting results are shown in Table 1. In general, the series and contact resistances (Rₛₑᵣᵢₑₛ and R_{P-CC}) are similar for the two electrodes, and do not change substantially during charging. This is expected, as the origins of these impedances should not be significantly impacted by coating of the post-calendered electrode. In contrast, the charge-transfer resistance (R_{CT}) decreases with increasing SOC for both electrodes, consistent with previous reports, [Refs. 51,54]

The most substantial difference between the control and coated electrode is that the LBCO 250x has a significantly lower SEI resistance (R_{SEI}) than the control (4.1 Ω-cm² vs. 17.3-17.8 Ω-cm²). This decreased SEI impedance can be rationalized by the facts that: (1) the LBCO coating successfully suppressed natural SEI formation during charging; and (2) the LBCO a-SEI has higher ionic conductivity than the natural SEI assuming that the natural SEI is of similar thickness, which is supported by previous reports. [Ref. 55] The lower R_{SEI} reduces overall cell polarization, consistent with (E) in FIG. 7.

Furthermore, at higher SOCs (120 mV and 83 mV), the decreased R_{SEI} in the LBCO-coated electrode results in 48% and 44% decreases in total impedance of the graphite electrode compared to the control. This could have important implications during fast charging, which amplifies current focusing near the top of the anode and results in an inhomogeneous SOC distribution throughout the electrode. [Refs. 3,5,9] Since Li plating initiates on particles or regions of the graphite electrode that are fully lithiated, [Refs. 56,57] the 4-fold reduction in R_{SEI} at high SOC could reduce the local driving force for Li plating.

2.5. Delayed Nucleation of Li Plating

To further investigate the impact of the a-SEI on Li plating, the 3-electrode cell was used to monitor the electrode potential during and after fast charging. (A) in FIG. 10 shows the electrode potential during 4C charging at a constant current to approximately 50% of the theoretical electrode capacity, followed by a rest period during which periodic EIS spectra were collected.

The voltage curves are substantially different for the control and LBCO 250x electrodes. The control electrode potential (orange) quickly decreases to a negative potential, reaches a local minimum, and then begins increasing towards 0 V vs Li/Li+ before reaching a plateau. The LBCO 250x electrode decreases more slowly, and does not reach a local minimum within the duration of the fast-charging.

The onset of Li plating has been correlated with the local minimum in the electrode potential during fast-charging. [Ref. 58] Because Li plating can only occur when the electrode potential drops below 0 V vs. Li/Li+, a more gradual potential drop during fast charging will delay the onset of Li plating. [Ref. 9] Thus, the more gradual voltage drop and lack of a voltage peak observed in the LBCO electrode are consistent with a suppression of Li plating. These phenomena are attributed to the decreased impedance described in the previous section.

There are also clear differences in the evolution of the measured potential during open-circuit conditions ((A) in FIG. 10), and corresponding EIS spectra (FIG. 17), following the fast-charging. The LBCO electrode potential quickly rises above 0 V vs. Li/Li⁺, and stabilizes around 120 mV. This is consistent with the equilibrium potential expected for a graphite electrode at 50% SOC. [Ref. 59] In contrast, the control electrode rises in potential much more slowly, and exhibits a deflection around 0 V vs. Li/Li+. This voltage profile has been previously shown to indicate that Li plating occurred during charging, and is associated with re-intercalation of the plated Li into graphite, [Refs. 58,60,61]

To further confirm the suppression of Li plating and improved rate capability, the SOC distribution and Li plating on the graphite electrodes were visualized using ex situ optical microscopy. Similar to the 3-electrode cells, 2-electrode half-cells were charged at a 4C rate to 50% SOC. They were then immediately disassembled (within 1 minute) and imaged to observe the amount of Li plating and the gradient in SOC through the thickness before the open-circuit rest period.

The resulting images are shown in (B) & (C) of FIG. 10. As graphite is lithiated, there is a clear change in color, allowing facile optical visualization of the local SOC distribution throughout the electrode. [Ref. 62] On the control electrode, there is a large amount (˜10 μm) of plated Li with a metallic luster on the top surface, and only a thin layer of fully-lithiated (gold colored) graphite underneath. In contrast, the LBCO 250x electrode has only trace amounts of plated Li and a gold-colored graphite region extends further in to the electrode depth. This indicates that a larger fraction of the lithium was intercalated into the graphite during fast charging.

We attribute the suppression of Li plating and improved homogeneity in the graphite SOC primarily to the reduced SEI impedance of the coated electrode. The reduced impedance makes the intercalation process more facile, requiring a lower overpotential and delaying the point at which the electrode potential drops below 0 V vs. Li/Li+. The improved homogeneity in SOC deeper within the electrode also indicates that reduced current focusing occurs near the top surface of the electrode. While a full mechanistic description of the spatial variations in current density may require follow-on modeling work, this result highlights the potential for a pure surface modification to enable fast charging of graphite despite the presence of electrolyte concentration gradients.

### 3. Conclusion

This study of Example 2 demonstrated the use of ALD to deposit a stable and ionically-conductive a-SEI on graphite, and demonstrated the impact of this coating on fast-charging performance. These results have led to several key findings:
(1) LBCO a-SEI coatings can eliminate natural SEI formation during preconditioning. The suppression of electrolyte decomposition could alleviate the need for costly and time-consuming preconditioning during battery manufacturing. The LBCO-coated electrode has an ASR of 4.1 Ω-cm², representing a four-fold reduction compared to the naturally formed SEI on the uncoated control electrode. This is possible because of the fact that LBCO is electrochemically stable (including at 0 V vs. Li/Li+), and a single-ion conductor with higher conductivity that the components of the natural SEI.
(2) LBCO a-SEIs dramatically reduce capacity fade during fast-charge cycling of pouch cells with commercially-relevant loadings. It resulted in a 40× improvement in cycle-life to 80% capacity retention with a 4C (15-min.) charging protocol. This was shown to be a result of reduced Li plating and the resulting increase in Coulombic efficiency. 3-electrode measurements and post-mortem optical imaging shows that the decreased SEI impedance delays the onset of Li plating, resulting in an improved homogeneity in SOC deeper within the electrode.
(3) The results of this study demonstrate that the SEI plays a key role in limiting fast-charging. To this point, the majority of fast-charging works have focused on improving mass transport in the liquid phase to enable faster rate charging. The present work of Example 2 challenges the idea that electrolyte transport must be improved to enable fast charging by doing so with an interfacial coating. This highlights that while mass transport plays a major role, the SEI also presents an opportunity for engineering enhanced fast-charging. In particular, coatings and other means of a-SEI formation could complement other fast-charging approaches such as 3D architectures and new electrolyte compositions. These distinct approaches improve high-rate cycling performance via different means and could yield synergistic benefits, enabling extreme fast charging beyond 4C rates. In addition, use of a single-ion conducting solid electrolyte as an a-SEI a has other important benefits such as reduced need for preconditioning and increased energy/Coulombic efficiencies.

4. Experimental Section/Methods

Electrode Fabrication: Graphite and NMC electrodes were fabricated using the pilot scale roll-to-roll battery manufacturing facilities at the University of Michigan Battery Lab, as reported previously. [Ref. 9] The graphite electrodes were fabricated with a total loading of 9.40 mg-cm⁻² including 94% natural graphite (battery grade, SLC1506T, Superior Graphite), 1% C65 conductive additive, and 5% CMC/SBR binder), resulting in a theoretical capacity of 3.18 mAh-cm⁻². The electrodes were calendered to a porosity of ˜32%. After coating, drying; calendaring, and punching, the full electrodes were moved into a Savannah S200 ALD reactor integrated into an argon glovebox for coating.

LiNi_{0.5}Mn_{0.3}Co_{0.2}O₂ (battery grade, NMC-532, Toda America) was used as the cathode material. The cathode formulation was 92 wt. % NMC-532, 4 wt. % C65 conductive additive, and 4 wt. % PVDF binder. The cathode slurry was cast onto aluminum foils (15 μm thick) with a total areal mass loading of 16.58 mg-cm⁻² and then calendered to 35% porosity. This yields an N:P ratio of 1.1-1.2.

Film Deposition and Characterization: The LBCO ALD film was deposited onto the electrodes using a modified version of the previously reported ALD process. [Ref. 29] This process uses lithium tert-butoxide, triisopropyl borate, and ozone precursors. In this case, the lithium Cert-butoxide pulse length was increased to 10 seconds, with a 20 seconds exposure, and the triisopropyl borate pulse was increased to 0.25 seconds, with 20 seconds exposure. These modifications were made to enable full coating of the high surface area electrode substrates. The deposition was conducted with a substrate temperature of 200° C. Film thickness was measured on Si wafer pieces placed adjacent to the graphite electrodes using spectroscopic ellipsometry. A Woollam M-2000 was used to collect data, which were then fit with a Cauchy layer on top of the native oxide of the Si, Film composition was characterized with X-ray photoelectron spectroscopy (XPS) using a Kratos Axis Ultra with monochromated Al Kα source. The XPS system is directly connected to an argon (Ar) glovebox to avoid all air exposure of samples. XPS data was analyzed with CasaXPS. Binding energies were calibrated using the C-C peak in the C 1s core scan at 284.8 eV. Film and electrode morphology were characterized by scanning electron microscopy using a Helios 650 nanolab dual beam SEM/FIB system. Electrode masses were measured using a Pioneer-series balance [Ohaus] inside an Argon glovebox, and electrode thicknesses were measured using an electronic thickness gauge (547-400S, Mitutoyo).

Cell Assembly: 2032 coin cells were assembled by punching circular electrodes from the larger pieces of ALD-coated and control electrodes. These electrodes were placed into the cells, followed by Entek EPH separator, 75 μL of electrolyte (1_{M} LiPF₆ in 3:7 EC/EMC, Soulbrain MI), the NMC electrode, a stainless steel spacer, and a Belleville washer. Cells were crimped at a pressure of 1000 psi. Cells were tap charged to 1.5 V, and then allowed to rest for 12 hours to allow for electrolyte wetting. Three C/10 constant current preconditioning cycles were then performed on each cell using a cell cycler (Landt instruments) prior to other electrochemical characterization.

Pouch cell electrodes (7 cm×10 cm) were punched and assembled into single-layer pouch cells in a dry room (<−40° C. dewpoint) at the University of Michigan Battery Laboratory. Each pouch cell consisted of an anode, a cathode, and a polymer separator (12 μm ENTEK). A NIP ratio of ˜1.2 was fixed for all pouch cells. Assembled dry cells were first baked in vacuum ovens at 50° C. overnight to remove residual moisture prior to electrolyte filling. 1_{M} LiPF₆ in 3/7 EC/EMC with 2% VC (SoulBrain MI) was used as the electrolyte. After electrolyte filling, pouch cells were vacuum-sealed and rested for 24 hours to allow for electrolyte wetting. Subsequently, two formation cycles were performed at C/20 and C/10 rates (one cycle for each C-rate). After formation, cells were transferred back into the dry room, degassed, and then re-sealed prior to subsequent cycling.

Electrochemical Characterization: Electrochemical impedance spectroscopy (EIS) was performed using an SP-200 or VSP potentiostat (Bio-logic USA). The spectra were fit to the equivalent circuit shown in FIG. 9 using the RelaxIS 3® software suite (rhd instruments GmbH & Co. KG), 3-electrode measurements were performed using a commercial electrochemical test cell (ECC-PAT-Core, EL-CELL GmbH) with a Li metal ring reference electrode. Preconditioning, rate tests, and fast-charge cycling were performed using a Maccor series 4000 cell cycler.

Post-mortem Characterization: XPS after preconditioning was performed as listed above. Scanning electron microscopy and focused-ion beam miffing was performed on a Helios G4 PFIB UXe (Thermo Fisher), The coin cells used for (B) & (C) in FIG. 10 were disassembled using a disassembly die (MTI Corp.) as soon as possible after fast-charging was completed (within 1 minute). The electrodes were immediately rinsed in dimethyl carbonate to remove residual electrolyte and halt Li transport through the liquid phase. The electrodes were torn to create a cross-section, and then imaged with a VHX-7000 digital microscope (Keyence Corp.).

Supplementary Information for Example 2

Thickness-dependent cycling performance of coin cells: The 250x and 500x LBCO coated cells exhibited significantly improved rate capability and capacity retention compared to the control (FIG. 15). The LBCO 50x cell was initially better than the control, but during extended cycling, eventually converged with the controls. This is consistent with the observation in (A) & (B) of FIG. 6 that the 50x coating was not sufficient to passivate the electrode surface. Furthermore, the heated control exhibited similar cycling performance to the unheated controls. Therefore, the observed differences in behavior are attributed to the coating itself, rather than the processing conditions.

Additional EIS fitting details: The circuit elements used to fit graphite electrodes typically include: (1) a resistance (Rₛₑᵣᵢₑₛ) associated with the ohmic drop; (2) a resistance (R_{P_CC}) associated with the contact between the graphite particles and between the graphite and the current collector; (3) a resistance (R_{SEI}) associated with ionic transport through the SEI; (4) a resistance (R_{CT}) associated with charge transfer processes; and (5) a diffusion element associated with solid-state diffusion within the graphite particles. R_{P-CC}, R_{SEI}, and R_{CT} each have a capacitance associated with them.

Constant phase elements were used for fitting R_{P-CC} and R_{CT} to account for the suppressed semi-circles that are observed. In addition, a Havriliak-Negarni (HN) term [Ref. 63] was used in conjunction with the SEI resistance to capture the asymmetry of the SEI impedance feature in the spectra. This asymmetry has been observed previously, [Ref. 54] and is generally accounted for by incorporating either a transmission line model or an HN element. It arises due to the combination of ionic transport through the SEI layer and the electrochemical reactions occurring at the surface of the SEI.

TABLE 1
Fit results for 3-electrode EIS data and fits shown in FIG. 9.
Area of working electrode was 2.545 cm².

| Sample | SOC | Rₛₑᵣᵢₑₛ | R_{P-CC} | Q_{P-CC} | α_{P-CC} | R_{SEI} | C_{HN} | T_{HN} | α_{HN} | β_{HN} | R_{CT} | Q_{CT} | α_{CT} | W_{diff.} |
|---|---|---|---|---|---|---|---|---|---|---|---|---|---|---|
| Units | (mV) | Ω | Ω | F | — | Ω | F | s | — | — | Ω | F | — | Ω · s^{-1/2} |
| Control | 200 | 4.12 | 1.16 | 1.24E−6 | 1 | 7.0 | 4.83E−4 | 8.13E−3 | 0.74 | 0.68 | 11.4 | 1.7E−2 | 0.85 | 1.2 |
| Control | 120 | 4.05 | 1.15 | 1.22E−6 | 1 | 6.8 | 5.24E−4 | 9.24E−3 | 0.68 | 0.74 | 1.95 | 1.9E−2 | 0.86 | 0.39 |
| Control | 83 | 3.94 | 1.11 | 1.28E−6 | 1 | 7.0 | 5.27E−4 | 9.14E−3 | 0.68 | 0.75 | 1.67 | 2.2E−2 | 0.93 | 0.48 |
| LBCO | 200 | 3.19 | 1.31 | 1.27E−6 | 1 | 1.6 | 2.73E−4 | 2.07E−3 | 0.95 | 0.49 | 10.2 | 2.11E−2 | 0.81 | 1.57 |
| 250x | | | | | | | | | | | | | | |
| LBCO | 120 | 3.20 | 1.32 | 1.24E−6 | 1 | 1.6 | 3.99E−4 | 4.30E−3 | 0.95 | 0.49 | 1.17 | 1.77E−2 | 0.89 | 0.50 |
| 250x | | | | | | | | | | | | | | |
| LBCO | 83 | 3.15 | 1.29 | 1.30E−6 | 1 | 1.6 | 4.02E−4 | 4.25E−3 | 0.95 | 0.49 | 1.62 | 1.57E−2 | 0.92 | 0.52 |
| 250x | | | | | | | | | | | | | | |

### REFERENCES

1. Zeng, X. et al. Commercialization of Lithium Battery Technologies for Electric Vehicles. Adv. Energy Mater. 9, 1900161 (2019).
2. Deng, J., Bae, C., Denlinger, A. & Miller, T. Electric Vehicles Batteries: Requirements and Challenges. Joule 4, 511-515 (2020).
3. Gallagher, K. G. et al. Optimizing Areal Capacities through Understanding the Limitations of Lithium-Ion Electrodes. J. Electrochem. Soc. 163, A138-A149 (2016).
4. Liu, Q. et al. Understanding undesirable anode lithium plating issues in lithium-ion batteries. RSC Adv. 6, 88683-88700 (2016).
5. Chen, K. et al. Enabling 6C Fast Charging of Li-ion Batteries with Graphite/Hard Carbon Hybrid Anodes, Adv. Energy Mater. 11, 2003336 (2021).
6. Sandhya, C. P., John, B. & Gouri, C. Lithium titanate as anode material for lithium-ion cells: A review. Ionics (Kiel). 20, 601-620 (2014).
7. Griffith, K. J. et al. Titanium Niobium Oxide: From Discovery to Application in Fast-Charging Lithium-ion Batteries, Chem, Mater. 33, 4-18 (2021).
8. Habedank, J. B., Kriegler, J. & Zaeh, M. F, Enhanced Fast Charging and Reduced Lithium-Plating by Laser-Structured Anodes for Lithium-ion Batteries. J. Electrochem. Soc. 166, A3940-A3949 (2019),
9. Chen, K.-H. et al. Efficient fast-charging of lithium-ion batteries enabled by laser-patterned three-dimensional graphite anode architectures. J. Power Sources 471, 228475 (2020).
10. Li, L., Erb, R. M., Wang, J., Wang, J. & Chiang, Y. M. Fabrication of Low-Tortuosity Ultrahigh-Area-Capacity Battery Electrodes through Magnetic Alignment of Emulsion-Based Slurries. Adv. Energy Mater. 9, 1-7 (2019).
11. Shim, J. H. & Lee, S. Characterization of graphite etched with potassium hydroxide and its application in fast-rechargeable lithium ion batteries. J. Power Sources 324, 475-483 (2016).
12. Cheng, Q., Yuge, R., Nakahara, K., Tamura, N. & Miyamoto, S. KOH etched graphite for fast chargeable lithium-ion batteries. J. Power Sources 284, 258-263 (2015).
13. Yang, X. G. et al. Asymmetric Temperature Modulation for Extreme Fast Charging of Lithium-Ion Batteries. Joule 3, 3002-3019 (2019).
14. Kim, D. S., Chung, D. J., Bae, J., Jeong, G. & Kim, H, Surface engineering of graphite anode material with black TiO2-x for fast chargeable lithium ion battery. Electrochim. Acta 258, 336-342 (2017).
15. Kim, D. S., Kim, Y. E. & Kim, H. Improved fast charging capability of graphite anodes via amorphous Al₂O₃ coating for high power lithium ion batteries. J. Power Sources 422, 18-24 (2019).
16. Tallman, K. R. et al. Improved Capacity Retention of Lithium Ion Batteries under Fast Charge via Metal-Coated Graphite Electrodes. J. Electrochem. Soc. 167, 160503 (2020).
17. Tallman, K. R. et al, Anode Overpotential Control via Interfacial Modification: Inhibition of Lithium Plating on Graphite Anodes. ACS Appl. Mater. Interfaces 11, 46864-46874 (2019).
18. Zhang, X. et al. Advanced Electrolytes for Fast-Charging High-Voltage Lithium-Ion Batteries in Wide-Temperature Range. Adv. Energy Mater. 10, 1-11 (2020).
19. Shi, J. et al. Improving the graphite/electrolyte interface in lithium-ion battery for fast charging and low temperature operation: Fluorosulfonyl isocyanate as electrolyte additive. J. Power Sources 429, 67-74 (2019).
20. Du, Z., Wood, D. L. & Belharouak, I. Enabling fast charging of high energy density Li-ion cells with high lithium ion transport electrolytes. Electrochem. commun. 103, 109-113 (2019).
21. Peled, E., Golodnitsky, D. & Ardel, G. Advanced Mod& for Solid Electrolyte Interphase Electrodes in Liquid and Polymer Electrolytes. J. Electrochem. Soc. 144, L208-L210 (1997).
22. Peled, E. The Electrochemical Behavior of Alkali and Alkaline Earth Metals in Nonaqueous Battery Systems—The Solid Electrolyte Interphase Model. J. Electrochem. Soc. 126, 2047-2051 (1979).
23. Aurbach, D., Markovsky, B., Weissman, I., Levi, E. & Ein-Eli, Y. On the correlation between surface chemistry and performance of graphite negative electrodes for Li ion batteries. Electrochim. Acta 45, 67-86 (1999).
24. Xu, K. Electrolytes and interphases in Li-ion batteries and beyond. Chem. Rev. 114, 11503-11618 (2014).
25. Zhang, Z. et al. New horizons for inorganic solid state ion conductors. Energy Environ. Sci. 11, 1945-1976 (2018).
26. Wood, K. N., Noked, M. & Dasgupta, N. P. Lithium Metal Anodes: Toward an Improved Understanding of Coupled Morphological, Electrochemical, and Mechanical Behavior. ACS Energy Lett. 2, 664-672 (2017).
27. Kazyak, E. et al. Atomic layer deposition and first principles modeling of glassy Li₃BO₃—Li₂CO₃ electrolytes for solid-state Li metal batteries. J. Mater. Chem. A 6, 19425-19437 (2018).
28. Kazyak, E. et al. Atomic Layer Deposition of the Solid Electrolyte Garnet Li 7 La 3 Zr 2 O 12. Chem. Mater. 29, 3785-3792 (2017).
29. Kazyak, E. et al. Atomic layer deposition and first principles modeling of glassy Li₃BO₃—Li₂CO₃ electrolytes for solid-state Li metal batteries. J. Mater. Chem. A 6, 19425-19437 (2018).
30. George, S. M. Atomic Layer Deposition: An Overview. Chem. Rev. 110, 111-131 (2010).
31. Jung, Y. S. et al. Unexpected improved performance of ALD coated LiCoO₂/graphite li-ion batteries. Adv. Energy Mater. 3, 213-219 (2013).
32. Jung, Y, S. et al. Ultrathin Direct Atomic Layer Deposition on Composite Electrodes for Highly Durable and Safe Li-ion Batteries. Adv. Mater. 22, 2172-2176 (2010).
33. Lee, M. L. et al. Atomic layer deposition of TiO2 on negative electrode for lithium ion batteries. J. Power Sources 244, 410-416 (2013).
34. Liu, J. et al. Minimizing Polysulfide Shuttle Effect in Lithium-Ion Sulfur Batteries by Anode Surface Passivation. ACS Appl. Mater. Interfaces 10, 21965-21972 (2018),
35. Yan. et al, Ultrathin Two-Dimensional Atomic Crystals as Stable Interfacial Layer for Improvement of Lithium Metal Anode. Nano Lett. 14, 6016-6022 (2014).
36. Meng, X., Yang, X,-Q. & Sun, X. Emerging Applications of Atomic Layer Deposition for Lithium-Ion Battery Studies. Adv. Mater. 24, 3589-3615 (2012).
37. Wang, X. & Yushin, G. Chemical vapor deposition and atomic layer deposition for advanced lithium ion batteries and supercapacitors. Energy Environ. Sci. 8, 1889-1904 (2015).

38, Ma, L. et at Atomic Layer Deposition for Lithium-Based Batteries. Adv. Mater. Interfaces 3, (2016),
39. Dahlberg, K. et al. ALD-Coated Graphite Anode Materials for Improved Cycle Life, Calendar Life, and Safety of Li-ion Cells. ECS Meet. Abstr. (2017) doi:10.1149/ma2017-02/1/116.

40, Jung, Y. S. et al, Enhanced stability of LiCoO2 cathodes in lithium-ion batteries using surface modification by atomic layer deposition. J. Electrochem. Soc. 157, 75-81 (2010).
41. Wu, K. et al. Controllable atomic layer deposition coatings to boost the performance of LiMnxCoyNil-x-yO2 in lithium-ion batteries: A review. J. Mater. Res. 35, 762-774 (2020).
42. Liu, J, & Sun, X. Elegant design of electrode and electrode/electrolyte interface in lithium-ion batteries by atomic layer deposition. Nanotechnology 26, 024001 (2015),
43, Zhao, Y., Zheng, K. & Sun, X. Addressing Interfacial Issues in Liquid-Based and Solid-State Batteries by Atomic and Molecular Layer Deposition. Joule 2, 2583-2604 (2018).
44. Wang, H.-Y. & Wang, F.-M. Electrochemical investigation of an artificial solid electrolyte interface for improving the cycle-ability of lithium ion batteries using an atomic layer deposition on a graphite electrode. J. Power Sources 233, 1-5 (2013).
45. Scott, I. D. et al, Ultrathin Coatings on Nano-LiCoo2 for Li-Ion Vehicular Applications. Nano Lett. 11, 414-418 (2011),
46. Leroy, S. et al. Surface film formation on a graphite electrode in Li-ion batteries: AFM and XPS study. Surf. Interface Anal, 37, 773-781 (2005),
47. Powell, C. J. & Jablonski, A. The NIST Electron Effective-Attenuation-Length Database. J. Surf. Anal. 9, 322-325 (2002).
48. Christopherson, J. P. Battery Test Manual for Electric Vehicles. http://www.inl.gov/technicalpublications/Documents/3952791.pdf (2015).
49. Wandt, J., Jakes, P., Granwehr, J., Eichel, R. A. & Gasteiger, H. A. Quantitative and time-resolved detection of lithium plating on graphite anodes in lithium ion batteries. Mater. Today 21, 231-240 (2018).
50. Chen, K.-H. et al. Dead lithium: mass transport effects on voltage, capacity, and failure of lithium metal anodes. J. Mater. Chem. A 5, 11671-11681 (2017).
51. Wang, C. Appleby, A. J. & Little, F. E. Electrochemical impedance study of initial lithium ion intercalation into graphite powders. Electrochim. Acta 46, 1793-1813 (2001).
52. Itagaki, M. et at Electrochemical impedance of electrolyte/electrode interfaces of lithium-ion rechargeable batteries: Effects of additives to the electrolyte on negative electrode. Electrochim. Acta 51, 1629-1635 (2006).
53. Illig, J. Physically based impedance modelling of lithium-ion cells. Physically based Impedance Modelling of Lithium-Ion Cells (2014). doi: 10.5445/KSP/1000042281.
54. Illig, J., Ender, M., Weber, A. & Ivers-Tiffée, E. Modeling graphite anodes with serial and transmission line models. J. Power Sources 282, 335-347 (2015).
55. Huang, W. et at Evolution of the Solid—Electrolyte Interphase on Carbonaceous Anodes Visualized by Atomic-Resolution Cryogenic Electron Microscopy. Nano Lett. 19, 5140-5148 (2019).
56. Verbrugge, M. W. & Baker, D. R. The influence of surface inhomogeneity on the overcharge and lithium plating of graphite electrodes. J. Phys. Energy 2, 014004 (2019).
57. Gao, T. et al. Interplay of Lithium Intercalation and Plating on a Single Graphite Particle. Joule 5, 393-414 (2021).
58. Fear, C. et al. In Operando Detection of the Onset and Mapping of Lithium Plating Regimes during Fast Charging of Lithium-Ion Batteries. ACS Appl. Mater. Interfaces 12, 30438-30448 (2020),
59. Winter, M., Besenhard, J. O., Spahr, M. E. & Novák, P. Insertion Electrode Materials for Rechargeable Lithium Batteries. Adv. Mater. 10, 725-763 (1998).
60. Konz, Z, M. et al. Detecting the Onset of Lithium Plating and Monitoring Fast Charging Performance with Voltage Relaxation. ACS Energy Lett. 5, 1750-1757 (2020).
61 Schindler, S Bauer, M., Petzl, M. & Danzer, M. A. Voltage relaxation and impedance spectroscopy as in-operando methods for the detection of lithium plating on graphitic anodes in commercial lithium-ion cells. J. Power Sources 304, 170-180 (2016).
62. Qi, Y. & Harris, S. J. In Situ Observation of Strains during Lithiation of a Graphite Electrode. J. Electrochem. Soc. 157, A741 (2010).
63. Havriliak, S. & Negami, S. A complex plane representation of dielectric and mechanical relaxation processes in some polymers. Polymer (Guildf). 8, 161-210 (1967).

The citation of any document is not to be construed as an admission that it is prior art with respect to the present invention.

Thus, the present invention provides a method for forming an electrode wherein a film is coated on electrode material particles or post-calendered electrodes.

This coating may be a lithium borate-carbonate film deposited by atomic layer deposition.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein. Various features and advantages of the invention are set forth in the following claims.

1. A method for forming a cathode, the method comprising:
(a) exposing cathode material particles to a lithium-containing precursor followed by an oxygen-containing precursor to form a coating on the cathode material particles;
(b) forming a slurry comprising the coated cathode material particles;
(c) casting the slurry on a surface to form a layer; and
(d) calendering the layer to form the cathode.

2. The method of claim 1 wherein step (a) further comprises exposing the cathode material particles to a boron-containing precursor followed by the oxygen-containing precursor to form the coating on the cathode material particles.

3. The method of claim 1 wherein:
the lithium-containing precursor comprises a lithium alkoxide.

4. The method of claim 2 wherein:
the boron-containing precursor comprises a boron alkoxide.

5. The method of claim 1 wherein:
the oxygen-containing precursor is selected from the group consisting of ozone, water, oxygen plasma, ammonium hydroxide, oxygen, and mixtures thereof.

6. The method of claim 2 wherein:
the lithium-containing precursor, the boron-containing precursor, and the oxygen-containing precursor are in a gaseous state.

7. The method of claim 1 wherein the cathode material particles are selected from the group consisting of lithium metal oxides wherein the metal is one or more of aluminum, cobalt, iron, manganese, nickel, vanadium, and lithium-containing phosphates having a general formula LiMPO₄ wherein M is one or more of cobalt, iron, manganese, and nickel.

8. The method of claim 1 wherein the cathode material particles are selected from the group consisting of cathode material particles having a formula LiNiₐMn_{b}Co_{c}O₂, wherein a+b+c=1 and a:b:c=(NMC 111), a:b:c=4:3:3 (NMC 433), a:b:c=5:2:2 (NMC 522), a:b:c=5:3:2 (NMC 532), a:b:c=6:2:2 (NMC 622), or a:b:c=8:1:1 (NMC 811).

9. The method of claim 1 wherein the coating is a film having a thickness of 0.1 to 50 nanometers.

10. (canceled)

11. (canceled)

12. (canceled)

13. (canceled)

14. (canceled)

15. (canceled)

16. (canceled)

17. A method for forming an anode, the method comprising:
(a) exposing anode material particles to a lithium-containing precursor followed by an oxygen-containing precursor to form a coating on the anode material particles;
(b) forming a slurry comprising the coated anode material particles;
(c) casting the slurry on a surface to form a layer; and
(d) calendering the layer to form the anode.

18. The method of claim 17 wherein step (a) further comprises exposing the anode material particles to a boron-containing precursor followed by the oxygen-containing precursor to form the coating on the anode material particles.

19. The method of claim 17 wherein:
the lithium-containing precursor comprises a lithium alkoxide.

20. The method of claim 18 wherein:
the boron-containing precursor comprises a boron alkoxide.

21. The method of claim 17 wherein:
the oxygen-containing precursor is selected from the group consisting of ozone, water, oxygen plasma, ammonium hydroxide, oxygen, and mixtures thereof.

22. The method of claim 18 wherein:
the lithium-containing precursor, the boron-containing precursor, and the oxygen-containing precursor are in a gaseous state.

23. (canceled)

24. The method of claim 17 wherein the coating is a film having a thickness of 0.1 to 50 nanometers.

25. (canceled)

26. (canceled)

27. (canceled)

28. (canceled)

29. (canceled)

30. (canceled)

31. (canceled)

32. A method for forming a cathode for an electrochemical device, the method comprising:
(a) forming a mixture comprising cathode material particles;
(b) calendering the mixture such that a porous structure is formed; and
(c) exposing the porous structure to a lithium-containing precursor followed by an oxygen-containing precursor to form a coating on the porous structure.

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. A method for forming an anode for an electrochemical device, the method comprising:
(a) forming a mixture comprising anode material particles;
(b) calendering the mixture such that a porous structure is formed; and
(c) exposing the porous structure to a lithium-containing precursor followed by an oxygen-containing precursor to form a coating on the porous structure.

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. A cathode for an electrochemical device, the cathode comprising:
cathode material particles selected from the group consisting of lithium metal oxides wherein the metal is one or more of aluminum, cobalt, iron, manganese, nickel, vanadium, and lithium-containing phosphates having a general formula LiMPO₄ wherein M is one or more of cobalt, iron, manganese, and nickel; and
a nanoscale film on at least a portion of a surface of the cathode material particles, the film comprising a lithium borate-based material, or a lithium carbonate based material or a mixture thereof.

64. (canceled)

65. (canceled)

66. (canceled)

67. (canceled)

68. (canceled)

69. (canceled)

70. (canceled)

71. (canceled)

72. (canceled)

73. An anode for an electrochemical device, the anode comprising:
anode material particles selected from the group consisting of graphite, soft carbon, hard carbon, silicon, silicon-carbon composites, lithium titanate (LTO), lithium metal, and mixtures thereof; and
a nanoscale film on at least a portion of a surface of the anode material particles, the film comprising a lithium borate-based material, or a lithium carbonate based material or a mixture thereof.

74. (canceled)

75. (canceled)

76. (canceled)

77. (canceled)

78. (canceled)

79. (canceled)

80. (canceled)

81. (canceled)

82. (canceled)

83. (canceled)
